(19) United States
(12) Patent Application Publication
(10) Pub. No.: US 2023/0367994 A1
(43) Pub. Date: Nov. 16, 2023

(54) HYPER NETWORK MACHINE LEARNING ARCHITECTURE FOR SIMULATING PHYSICAL SYSTEMS

(71) Applicant: NEC Laboratories Europe GmbH, Heidelberg (DE)

(72) Inventors: Francesco Alesiani, Heidelberg (DE); Makoto Takamoto, Heidelberg (DE)

(21) Appl. No.: 17/969,721

(22) Filed: Oct. 20, 2022

(30) Foreign Application Priority Data
May 13, 2022 (EP) 22173344.7

(51) Int. Cl. G06N 3/045; G06F 30/20; G06F 17/14

(52) U.S. Cl. CPC G06N 3/045; G06F 30/20; G06F 17/142

(57) ABSTRACT

A method for operating a hyper network machine learning system, the method including training a hyper network configured to generate main network parameters for a main network and generating, using the trained hyper network, the main network with the main network parameters, the main network having a machine learning architecture that models a spatial domain and a frequency domain to simulate a physical system.

### CROSS-REFERENCE TO RELATED APPLICATIONS

Priority is claimed to European Provisional Patent Application No. 22173344.7, filed on May 13, 2022, the entire disclosure of which is hereby incorporated by reference herein.

### FIELD

The present disclosure relates to a method, system, and computer-readable medium for a hyper network machine learning model for simulating physical systems.

### BACKGROUND

Numerical simulations are used to various industries and technical specialties, and can be used, for example, to design new cars, airplanes, molecules and drugs, and even to predict weather. While these numerical simulations can be extremely important, they also often require large amounts of computational power and require fast adaptation to new conditions and hypothesis.

Physic-informed machine learning aims to build surrogate models for real-world physical systems governed by partial differentiable equations. One of the more popular recently proposed approaches is the Fourier Neural Operator (FNO), which learns the Green's function operator for partial differential equations (PDEs) based only on observational data. These operators are able to model PDEs for a variety of initial conditions and show the ability of multi-scale prediction. However, this model class is not able to model a high variation of the parameters of some PDEs. For example, PDEs may be used to describe various physical systems, from large-scale dynamic systems such as weather systems, galactic dynamics, airplanes, or cars, to small-scale systems such as genes, proteins, or drugs. In traditional approaches, such as dynamic numerical simulations, the use of domain expertise is the basis for designing numerical solvers. However, such traditional approaches suffer from a host of disadvantages. For example, traditional approaches may suffer from numerical instabilities, long simulation times, and a reduced adaptability for use with hybrid hardware applications involving use of Graphics Processing Units (GPUs) and vector computing. Traditional approaches may also have difficult or unclear ways to include direct numerical observation from instrumental measurements, making it particularly difficult to model noisy data or utilize sparse observational data into a numerical simulation. Large computational resource requirements, including large memory requirements, may be required. Dedicated software is often also required for data and computational parallelization. Traditional approaches also struggle with generalization, making it difficult to apply a trained State of the Art (SOTA) machine learning model, like an FNO model, to unseen data.

### SUMMARY

A method for operating a hyper network machine learning system, the method comprising training a hyper network configured to generate main network parameters for a main network and generating, using the trained hyper network, the main network with the main network parameters, the main network having a machine learning architecture that models a spatial domain and a frequency domain to simulate a physical system.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIGS. 1a and 1b illustrate systems including a hyper network and main network;

FIG. 2 illustrates a frequency and spatial main network;

FIG. 3 illustrates a conditional network;

FIG. 4 illustrates a meta-network;

FIG. 5 illustrates a weather forecasting network;

FIG. 6 illustrates a block diagram of an interaction with a numerical simulator;

FIG. 7a illustrates a block diagram of hyper parameter optimization for a numerical simulator;

FIG. 7b illustrates a block diagram of hyper-FNO configured to integrate simulation and observation for domain transfer;

FIG. 8a illustrates a training model for blood flow modeling;

FIG. 8b illustrates a test model for blood flow modeling;

FIG. 9 illustrates water pollution simulation data;

FIG. 10 illustrates oil exploration and simulation data;

FIG. 11 illustrates a Hyper Fourier Neural Operator;

FIGS. 12a-12d illustrate a comparison of FNO and hyper-FNO in testing and training;

FIG. 13 illustrates a block diagram of a processing system;

FIGS. 14a-14b illustrate a multilayer perceptron configuration for a computational fluid dynamics simulation; and

FIGS. 14c-14d illustrate a multilayer perceptron configuration for a reaction-diffusion simulation.

### DETAILED DESCRIPTION

The present disclosure provides an improved machine learning architecture for simulating and making predictions about physical systems. According to an aspect of the present disclosure, a hyper network machine leaning architecture is provided, which includes a hyper network and a main network. The hyper network is configured to learn the behavior of the main network and train and/or configure the main network. The main network, once trained, is configured to accurately model (simulate) a target physical system. The main network and/or the hyper network are configured with spatial components and frequency components—for example, the main network and/or the hyper network may use a Fourier Neural Operator (FNO) machine learning architecture.

Advantageously, machine learning systems configured according to aspects of the present disclosure accelerate the computation of numerical solutions of partial differential equations (PDEs) using data driven machine learning as compared to the state of the art. Aspects of the present disclosure also provide for a variety of advantages over traditional models performing numerical simulation methods, such as an increase in model accuracy for new parameter configurations, increased simulation speed for new configurations, and integrating models with observational data. Other advantages include enabling efficient initial parameter estimates for new system configurations, compatibility with hybrid hardware such as GPUs, and easy adaptation due to inference times that are proportional to the number of parameters in a model (e.g., an FNO model). The disclosed machine learning architecture provides these substantial improvements over the state of the art, while only adding a small additional memory requirement.

A first aspect of the present disclosure provides a method for operating a hyper network machine learning system, the method comprising training a hyper network configured to generate main network parameters for a main network, and generating, using the trained hyper network, the main network with the main network parameters, the main network having a machine learning architecture that models a spatial domain and a frequency domain to simulate a physical system.

According to a second aspect of the present disclosure, the main network of a method according to the first aspect may have a Fourier neural operator architecture comprising a plurality of Fourier layers each having a frequency and spatial component, and wherein the hyper network generating the main network parameters comprises generating parameters for the Fourier layers.

According to a third aspect of the present disclosure, during training of the hyper network in a method according to at least one of the preceding aspects, the hyper network modifies the Fourier layers based on a Taylor expansion around a learned configuration to determine updated parameters for the Fourier layers.

According to a fourth aspect of the present disclosure, the updated parameters are changed in both the frequency and spatial component in a method according to at least one of the preceding aspects.

According to a fifth aspect of the present disclosure, a method according to at least one of the preceding aspects may further comprise obtaining a dataset based on experimental or simulation data generated with different parameter configurations, the dataset comprising a plurality of inputs and a plurality of outputs corresponding to the inputs, wherein the hyper network is trained using the dataset.

According to a sixth aspect of the present disclosure, the training in a method according to at least one of the preceding aspects may comprise simulating, via the main network generated with the main network parameters, the physical system to determine a simulation result based on the at least one input of the dataset comparing the simulation result against at least one output corresponding to the at least one input from the dataset, and updating the main network parameters based on the comparison result.

According to a seventh aspect of the present disclosure, the training of the hyper network in a method according to at least one of the preceding aspects is iteratively conducted until the simulation result is within a predetermined tolerance threshold when compared to the at least one output.

According to an eighth aspect of the present disclosure, a method according to at least one of the preceding aspects may further comprise receiving system parameters by the hyper network, the system parameters corresponding to the physical system targeted for simulation, wherein generating the main network with the main network parameters comprises the hyper network generating the main network parameters based on the hyper network parameters and the system parameters.

According to a ninth aspect of the present disclosure, the hyper network in a method according to at least one of the preceding aspects may comprise Fourier layers each having a frequency and spatial component with corresponding hyper network parameters, and wherein the method further comprises receiving system parameters by the hyper network, the system parameters being configured to adapt the Fourier layers to the physical system targeted for simulation.

According to a tenth aspect of the present disclosure, the hyper network in a method according to at least one of the preceding aspects may comprise Fourier layers each having a frequency and spatial component with corresponding hyper network parameters, wherein the method further comprises adapt the Fourier layers to the physical system targeted for simulation based on system parameters, and wherein the system parameters are determined by learning a representation of the system parameters according to a bilevel problem.

According to an eleventh aspect of the present disclosure, the hyper network in a method according to at least one of the preceding aspects may comprise hyper network parameters corresponding to the spatial domain and the frequency domain, wherein training the hyper network comprises updating the hyper network parameters using stochastic gradient descent based on a training database comprises input and output pairs until a target loss threshold is reached, and wherein the generating of the main network is performed after completing the training of the hyper network and comprises receiving system parameters associated with the target physical system and generating the main network parameters based on the hyper network parameters and the system parameters.

According to a twelfth aspect of the present disclosure, a method according to at least one of the preceding aspects may comprise instantiating the main network on a computer system and operating the man network to simulate the target physical system.

According to a thirteenth aspect of the present disclosure, a method according to at least one of the preceding aspects may comprise receiving input data, simulating the physical system based on the input data to provide a simulation result and determining whether to activate an alarm or hardware control sequence based on the simulation result.

According to a fourteenth aspect of the present disclosure, a method according to at least one of the preceding aspects may comprise parameterizing a meta-learning network by modifying only system parameters.

According to a fifteenth aspect of the present disclosure, in a method according to at least one of the preceding aspects, the main network based on the main network parameters generated by the hyper network includes fewer parameters than the hyper network.

According to a sixteenth aspect of the present disclosure, a tangible, non-transitory computer-readable medium is provided having instructions thereon which, upon being executed by one or more hardware processors, alone or in combination, provide for execution of a method according to at least one of the first through fifteenth aspects.

According to a seventeenth aspect of the present disclosure, a system is provided comprising one or more hardware processors which, alone or in combination, are configured to provide for execution of the steps of training a hyper network configured to generate main network parameters for a main network and generating, using the trained hyper network, the main network with the main network parameters, the main network having a machine learning architecture that models a spatial domain and a frequency domain to simulate a physical system.

According to aspects of the present disclosure, a class of alternative operations for the generation of FNO parameters is disclosed, and the affine transformation in the hyper network is shown to be sufficient, thus reducing the number of additional network parameters.

According to an aspect of the present disclosure, a method is provided for use of a hyper network that generates a smaller network that is used to simulate a physical system after being trained on a large dataset corresponding to a configuration. The hyper network may have a limited number of parameters, with frequency and spatial layers being modified based on a Taylor expansion around a learned configuration, where a change is also learned. A machine learning architecture may be used that models the space and frequency domain, and the learned change in the parameters is on both of the two domains driven by the parameters of the system. The external parameters may adapt the smaller network (which may be a FNO model) to the specific (i.e., target) configuration/environment/use cases. If the external parameters are not known, a training procedure may be run that includes learning a representation of the parameters described as a bi-level problem. The smaller network may be instantiated and used to make predictions based on inputs. When few samples are given, the generated smaller network may be individually trained.

According to an aspect of the present disclosure, a method is provided that includes: collecting experimental data and/or simulation data over different parameter configurations; training of a hyper network over the experimental and/or simulation dataset; querying the hyper network with specific parameters to obtain main network parameters; and using the main network parameters for a target configuration.

According to an aspect of the present disclosure, a hyper network system architecture may include two networks that work together: a hyper network and a main network. The hyper network generates and/or reconfigures the main network. The main network—after being trained on a training dataset—is used to simulate a target physical system. As used in the present disclosure a “hyper network” and a “main network” are machine learning models, in particular neural networks using FNOs.

The hyper network may be configured to receive, as inputs, parameters (or representations of parameters) of the system and provide the parameters of the main network. The hyper network may then learn the behavior of the main network (e.g., during the training phase) and use that information to reconfigure the main network (e.g., by sending updated parameters to the main network to improve the performance (e.g., accuracy) of the main network). Additionally or alternatively, the hyper network may interpolate the configuration of the main network and assist in predicting the output of the main network in new configurations, whose parameters were not seen before (or during) training, after being trained in calibrated simulations.

According to an aspect of the present disclosure, the hyper network is trained by minimizing a loss function that includes parameters for the main network. The hyper network uses each layer of an FNO, each layer including spatial and frequency components. Additionally or alternatively, the hyper network parameters may be updated using a stochastic gradient descent, as exemplified by the following formula:

θ′=θ−∇_{θ} [symbol] (y−ŷ(ψ(θ(λ)),x) [Formula I]

A derivative of a parameter θ of the main network is thus determined based on a gradient comparing dataset output y and a predicted output ŷ that is based on a function P of main parameter θ and system parameters λ, as well as a dataset input x. By repeated use of the foregoing formula and iterative updating of the hyper network parameters, ideal parameters of the hyper network can be determined, thereby “training” the hyper network and enabling the hyper network to provide optimized parameters θ to a main network. Additionally or alternatively, the hyper network may be trained together with the main network based on datasets used to compare predicted values with known calculated values.

The main network is configured as the network that receives input data (e.g., physical simulation input data) and outputs one or more predictive results (e.g., the predictive result of the simulation). In the training phase, the main network may receiving input training data, which is from a training data set, which includes the training input data and the complementary known training output data. The output predicted by the main network in the training phase may then be compared against the known training output data, and the parameters of the main network may be adjusted (e.g., by or with the assistance of the hyper network) based on that comparison. In an online phase, the main network may receive input data on which a prediction is to be made—i.e., no corresponding output data yet exists and the output is yet-unknown to the system; run a simulation of the physical system based on the input data to predict an outcome; and generate output data corresponding to the predicted outcome.

The main network is “smaller” than the hyper network—e.g., the main network may have smaller architecture with fewer parameters or layers than the hyper network—making the main network more computationally efficient to run test simulations upon. On the other hand, the hyper network utilizes a large architecture (at least in part) to generate the smaller main network (or at least its parameters). The larger architecture of the hyper network may include a higher number of parameters to enable it to be trained efficiently. The smaller main network (once trained/updated) can be deployed for simulating the target physical system, and is generally more efficient (e.g., as far as the utilization of computational resources) at simulating the physical system as compared to not only the larger hyper network, but also to other machine learning models that were not generated and/or configured using a hyper network. The larger hyper network may not be used in this deployed simulation.

According to an aspect of the present disclosure, the main network may have parameters that are not generated by the hyper network, but are nevertheless trained with parameters generated by the hyper network. For example, one layer of an FNO may be generated by the hyper network, while other layers are not. In another example, while both frequency and spatial parameters are implemented in the main network, only the frequency parameters (or, conversely, only the spatial parameters) are generated by the hyper network.

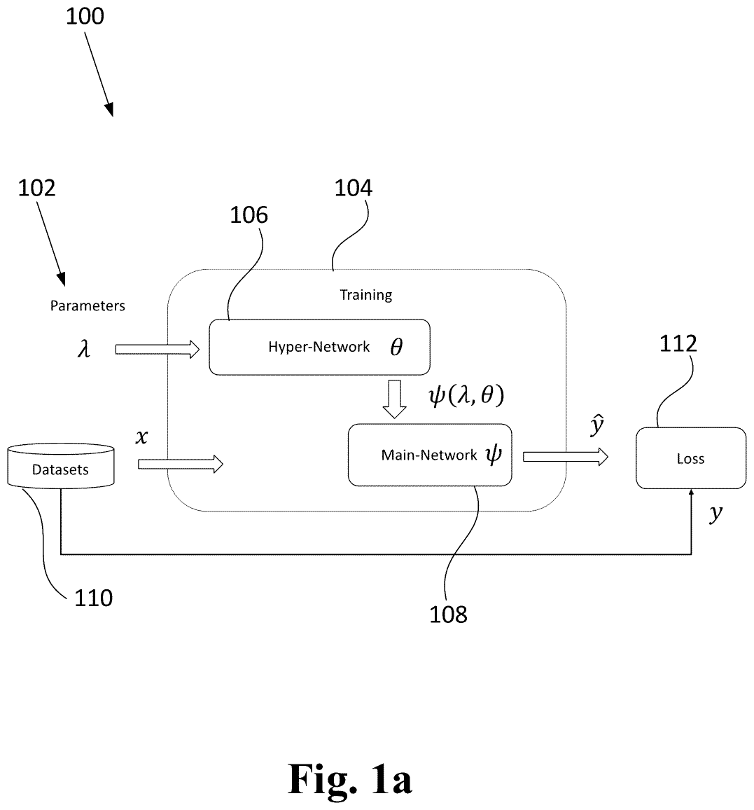

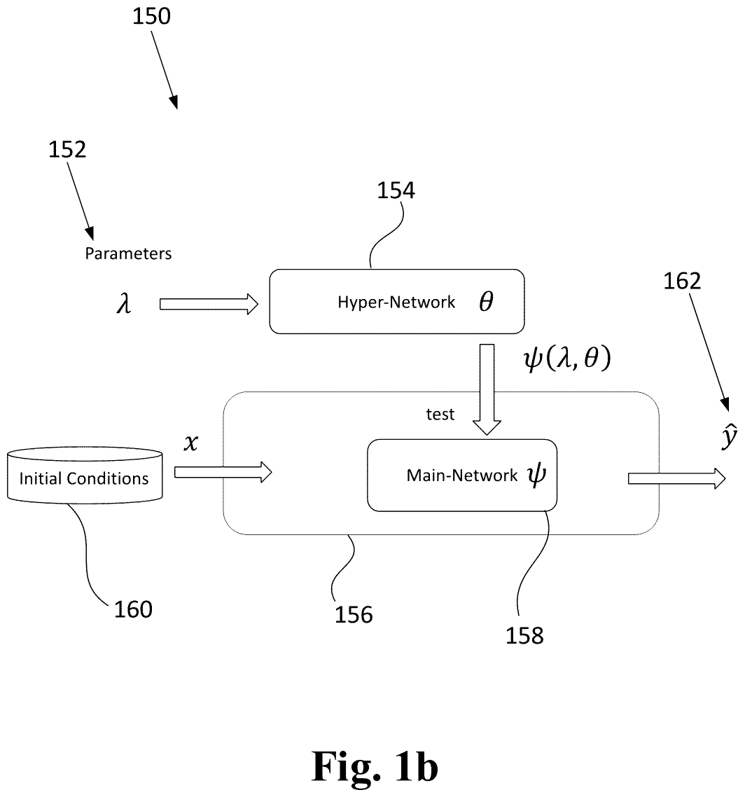

FIGS. 1a and 1b illustrate systems 100, 150 that each include a hyper network and main network. In the system 100 of FIG. 1a, system parameters (λ) 102 of the system 100 are input to a training module 104 (the system parameters (λ) 102 may be preconfigured externally to adapt the model to a specific target physical system simulation use case). The training module 104 includes a hyper network 106, which has hyper network parameters θ and is configured to receive as inputs the system parameters (λ) 102. The hyper network 106, using the system parameters (λ) 102 and its hyper network parameters θ, outputs main network parameters ψ to a main network 108. The main network 108 receives the main network parameters ψ from the hyper network 106. The main network 108 is configured as a numerical simulation model that receives data inputs x and outputs data results 9. In the illustrated system 100, a dataset 110 is test dataset that includes both data inputs x and corresponding data outputs y for each data input x. By comparing the data results y output by the main network 108 against data outputs y for a given data input x, the system is configured to determine a loss 112 that correlates to (or is indicative of) an accuracy of the main network's simulation model. Until a loss 112 that is within a predetermined or dynamically determined tolerance threshold, the training module 104 may iteratively adjust the hyper network parameters θ; thereby, refining the accuracy of the main network parameters ψ. In this manner, the training module 104 is configured to iteratively train the main network 108 until a sufficiently trained main network 108 is able to substantially predict (within a margin of error or acceptable tolerance), data results y based on corresponding data inputs x of the datasets 110. In some embodiments, the parameters of the hyper network 106 are updated using stochastic gradient descent.

The training dataset may be obtained by collecting experimental data and simulation data, e.g., over different parameter configurations, for the target physical system.

FIG. 1b illustrates a system 150 for generating and running tests (simulations) with a main network 158. The system 150 includes a hyper network 154, which receives system parameters (λ) 152 as inputs and outputs main network parameters ψ to generate the main network 158. The system parameters (λ) 152 may be preconfigured externally to adapt the model to a specific target physical system simulation use case. The hyper network 154 may have been previously trained and/or configured with hyper network parameters θ for providing an accurate simulation model. The main network parameters ψ are generated based on the received system parameters (λ) 152 and the hyper network parameters θ. The main network is then instantiated in a test system 156 using the generated main network parameters ψ. A test system 156 is configured to operate the main network 158 to receive as inputs, initial conditions 160, simulate the target physical system based in the initial conditions to make a prediction, and to output results 162 based on the prediction made.

It will be readily appreciated that the system 100 of FIG. 1a and the system 150 of FIG. 1b may be embodied as separate hardware and/or software, thus allowing a training module 104 to separately train a separate or distinct main network 108 while a testing module 156 performs testing on an already trained main network 158. In some embodiments, systems 100, 150 are embodied within the same hardware and/or software, thus allowing compact and resource-efficient concentration of computing power to perform both a training and testing on a given numerical simulation.

According to an aspect of the present disclosure, the hyper network and/or the main network may be configured with a Fourier Neural Operator (FNO) architecture. For example, the main network may include multiple layers of elements of the form:

x=Wx+ [symbol] ⁻¹(R [symbol] (x)) [Formula II]

In the foregoing Formula II, [symbol] is the Fourier transform, x are the features of the network and W and R are matrices representing the parameters of the layer. The hyper network generates the parameters for a Fourier layer of the main network according to the formula:

xₗ₊₁=Wₗ(λ,θₗ)xₗ+ [symbol] ⁻¹(Rₗ(λ,θₗ) [symbol] (xₗ)) [Formula III]

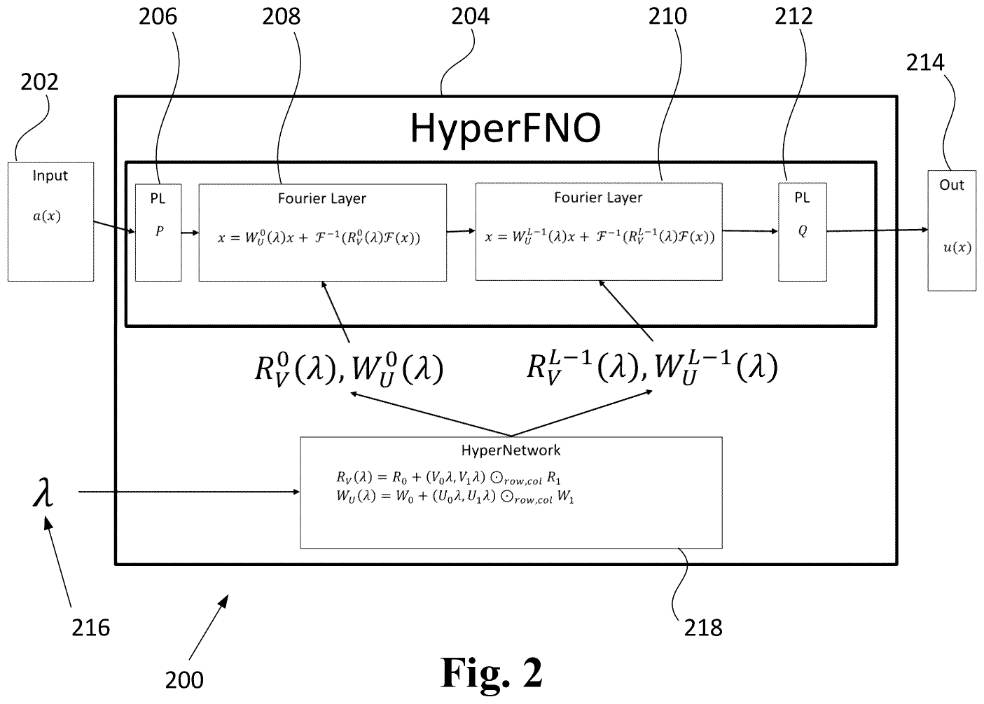

FIG. 2 illustrates a frequency and spatial main network 200. Specifically, FIG. 2 illustrates a hyper-FNO 204 that includes a hyper network 218 configured to receive system parameters 216. The hyper network 218 generates parameters specific to Fourier layers 208, 210 of a main network. The Fourier layers 208, 210 are then configured based on these generated parameters. For example, for Fourier layers defined according to Formula III above, the parameters for each layer (e.g. R_{V}⁰, W_{V}⁰ & R_{V}^{L-1}, W_{U}^{L-1}) may be determined according to Formulas IV and V, described below (where U and Vindicate that the parameters are generated by the hyper network 218).

An input 202 is received by a first parameter layer 206. The parameter layer 206 is then used in first Fourier layer 208. A second Fourier layer 210 receives an output from the first Fourier layer 208. A second parameter layer 212 receives the output of the second Fourier layer 210 and outputs output 214. The first parameter layer 206 and second parameter layer 212 include projection operators P and Q for reducing dimensions and expanding and contracting the input 202 in the hyper-FNO 204. Projection operators P and Q can be generated by the hyper network. 218.

Hyper network machine learning architectures implemented according to the present disclosure can be further understood to comprise addition features or modification to the foregoing aspects, thereby realizing additional advantages over traditional machine learning models executing numerical simulations.

According to one aspect, estimation of the parameters can be accomplished in a model agnostic manner. For example, a bi-level formulation and update rule can be implemented to jointly learn the representation of unknown parameters of a system. The bi-level formulation may include solving an optimization problem composed of two sub-problems that depend on each other. One problem is referred to as the outer problem and the other is referred to as the inner problem. The general form of the bi-level formulation is:

$${min}_{x} f ( x , λ ) , where$$

$$λ = arg {min}_{λ′} g ( x , {λ}^{′} ) .$$

λ is the parameter of the PDE describing a particular model, which may not be known in advance, so jointly solving for the parameters may be required during training. In the bi-level formulation, ƒ and g are loss functions and x is the solution of the PDE. ƒ and g may be the same loss function, but computed on different datasets.

According to one aspect, estimation of the parameters with new environments is accomplished. When a new environment is observed, the parameters of the system may not be known, and thus a few samples may be used to first detect the parameters of the system and then possibly use the same or additional samples to update the predictive model that is later used at test time. For example, the first ten samples of a solution may be observed and used to derive the parameter λ. The parameter λ may then be used to predict the rest of the solution.

According to one aspect, main network calibration can be carried out by using the hyper-FNO to calibrate the main network. For example, the hyper-FNO can be trained based on multiple configurations of the main network, and then the hyper-FNO can be used as a surrogate model. The optimal parameters for a desired condition or specific output can then be found. The main model with the new discovered parameters can be run to determine a more accurate prediction, if necessary.

According to an aspect of the present disclosure, a conditional network can be established to use a conditional neural network where the network receives as inputs the parameters of the system (via PDEs) and inputs of the main network (e.g., the initial condition, the forcing term, or other physics-related functions). During training, all the parameters of the system are learned. At test time, if data of the new environment is available, only the last layers are trained. In this manner, training efforts and resources are concentrated or limited to test time, thereby increasing simulation efficiency, but, as a trade-off, an advantage in reduced memory size may be lost.

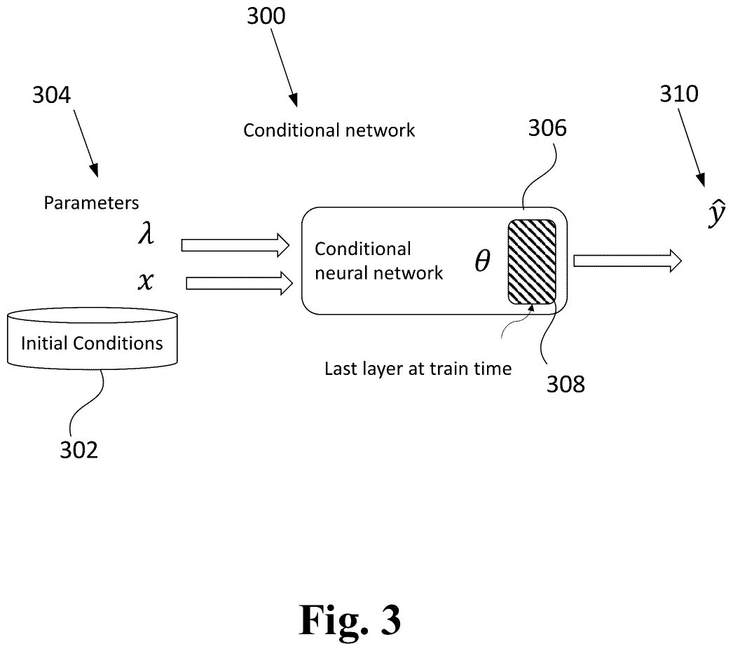

FIG. 3 illustrates a conditional network 300 wherein a conditional neural network 306 receives as inputs system parameters 304 and initial conditions 302. The initial conditions 302 may include forcing terms or other physic related functions of a given system. The conditional neural network 306 includes a last layer 308, which, during training, outputs a result 310. During training, all parameters 304 relevant to the network conditional neural network 306 are learned. In some embodiments, if data of a new environment is available during testing, only last layer 308 is trained. This constrains training resources and efforts to test time, but at a cost of increased memory size requirement.

According to an aspect of the present disclosure, a meta-learning network is provided, wherein the parameters of the main network are selected to work in all configurations or a few samples are used to specialized to a specific scenario. In an embodiment, a reptile approach is used, wherein the parameters of the meta-learning network is updated only after a few iterations of updating the main network on a new task or a new configuration. In an embodiment, a Model Agnostic Meta Learning (MAML) approach is used, wherein the meta-learning model is the same as the main network. In this embodiment, a few gradient descents are used based on a sample for the specific new task or new configuration.

In addition, the structure of the meta-learning network is parametrized by λ and in the adaptation phase only λ is modified, according to the formulas:

R_{V}(λ)=R₀+(V₀λ,V₁λ)⊙_{row,col}R₁ [Formula IV]

W_{U}(λ)=W₀+(U₀λ,U₁λ)⊙_{row,col}W₁ [Formula V]

or

R_{V}_{₀}_{,V}_{₁}(λ)=rᵢⱼₗ^{FT}(λ)=rᵢⱼₗ⁰(1+v₀^{ik}λₖ^{q}v₁^{jk}v₂^{lk}) [Formula VI]

W_{U}_{₀}_{,U}_{₁}(λ)=wᵢⱼₗ^{XT}(λ)=wᵢⱼₗ⁰(1+u₀^{ik}λₖu₁^{jk}u₂^{lk}) [Formula VII]

According to an aspect of the present disclosure, the system parameters λ are modelled as a distribution and in phase of inference drawn by a distribution λ˜N(μ, Σ), where μ, Σ parameters are learned in a variational approach using a variational trick. In this way a statistic of the results with error intervals can be built. Specifically, a variational trick may include using a fixed distribution without parameters as a sample and subsequently transforming the sample with parameters that are trainable. For example, a variable e may be modeled as a normal distribution with a mean of zero and a variance of one. A new variable x can then be built such that:

x=αe+β,e˜N(0,1),

where α and β are trainable parameters. A model is defined by

W(λ)=W¹(λ)e+W⁰(λ),e˜N(0_{d},1_{d}),

where W¹(λ), W⁰(λ) are modelled as in Formula VII and R¹(λ), R⁰(λ) as Formula VI.

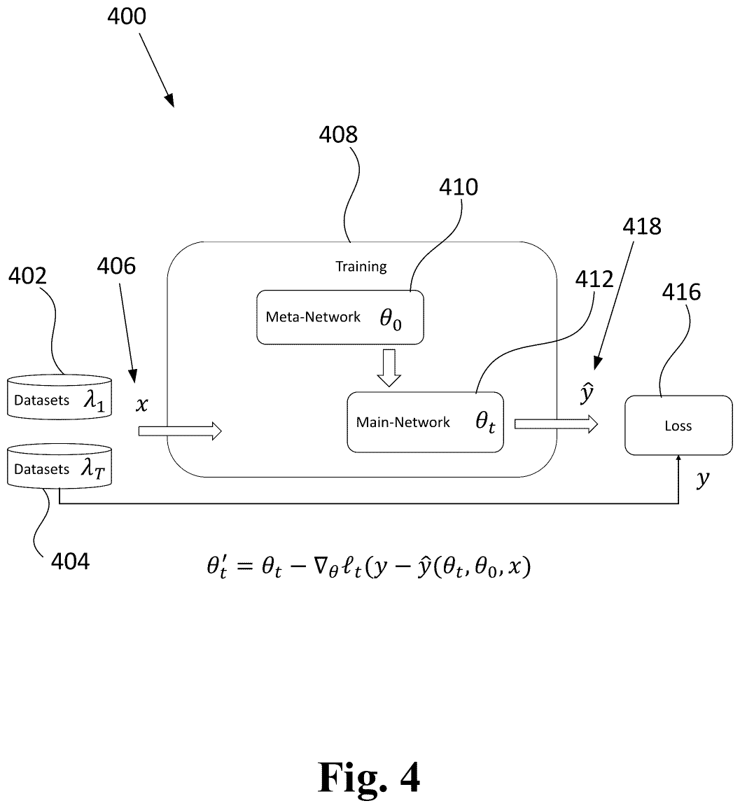

FIG. 4 illustrates a meta-network system 400, wherein parameters 402 of the main network 412 are selected to work well in all configurations or a few samples are used to specialize the main network 412 to a specific scenario. The meta-network system 300 includes a training module 408 having a meta-network 410 and a main network 412. The training module is configured to receive data inputs from datasets 402, 404 and to output a result 418. The datasets 402, 404 include parameterization data, which the meta-network 410 is configured to receive in order to train the main network 412. A loss 416 is determined by comparing the result 418 with data from the dataset 404. The loss is used to determine whether the main network 412 is sufficiently trained, or if further iterative training should be carried out to further train the main network 412. In some embodiments, a so-called “reptile approach” is used in which the parameters of the meta-network 410 are updated only after a few iterations of training or updating the main network on a new task or configuration. In some embodiments, a so-called Model Agnostic Meta Learning (MAML) approach is used.

In an exemplary implementation of an aspect of the present disclosure, numerical simulations may be used to provide large weather forecasts and simulation acceleration for high-performance computing (HPC). In such an implementation, the use of hyper-FNO is advantageous for accelerating the study of weather forecast and support to the government and research community to perform simulations in various scenarios. Furthermore, the use of the hyper-FNO facilitates parameter estimation and inverse problem solving. Parameter estimation is particularly benefitted in that an infinite parameter space is drastically reduced with the help of hyper-FNO's efficient parameter estimation.

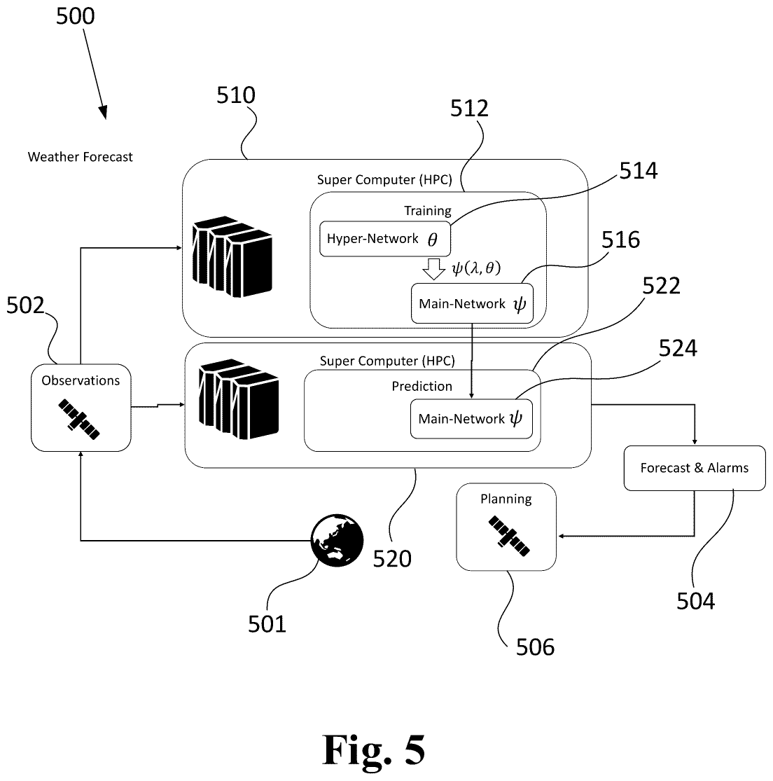

FIG. 5 illustrates a weather forecasting network system 500 including a first super computer or HPC 510 and a second super computer or HPC 520. Both the first and second super computers 510, 520 are configured to receive observation data from observations 502, such as measured observational data corresponding to events in the real world 501. The first super computer 510 includes a training module 512 with a hyper network 514 and a main network 516. The first super computer 510 is configured to receive observational data in order to train the main network 516. Outputs of the main network 516 are then used in a prediction main network 524 that is included in a prediction module 522 of the second super computer 520. A weather prediction is determined by the prediction main network 524, which his configured to output the weather prediction to a forecast & alarm system 504, and subsequently to a planning system 506. Due to the efficient parameter estimation afforded by the hyper network 514, predictions in a weather forecast can be produced on an accelerated time scale and an otherwise infinite parameter space can be drastically reduced. Furthermore, weather forecast predictions using the weather forecasting network system 500 have increased prediction accuracy in comparison to traditional forecast systems, as accuracy is known to decrease as prediction time increases and PDEs by their nature may lead to chaotic results.

In traditional approaches, several numerical simulations are performed based on observational data, and statistical data is used to produce a forecast. However, the accuracy of a prediction degrades as prediction time increases because of the chaotic nature of PDEs. Some approaches combat this by increasing the sample of statistical data used to produce the forecast, which can be difficult because of significantly increased computational costs.

In an aspect of the present disclosure, traditional simulation results are combined with hyper-FNO's predictions. The hyper-FNO's predictions can be more quickly obtained (and thus a higher quantity of predictions obtained in a given time) in comparison to predictions by a traditional simulation thanks to efficient model calculation and the fact that the various parameters could be easily taken into account.

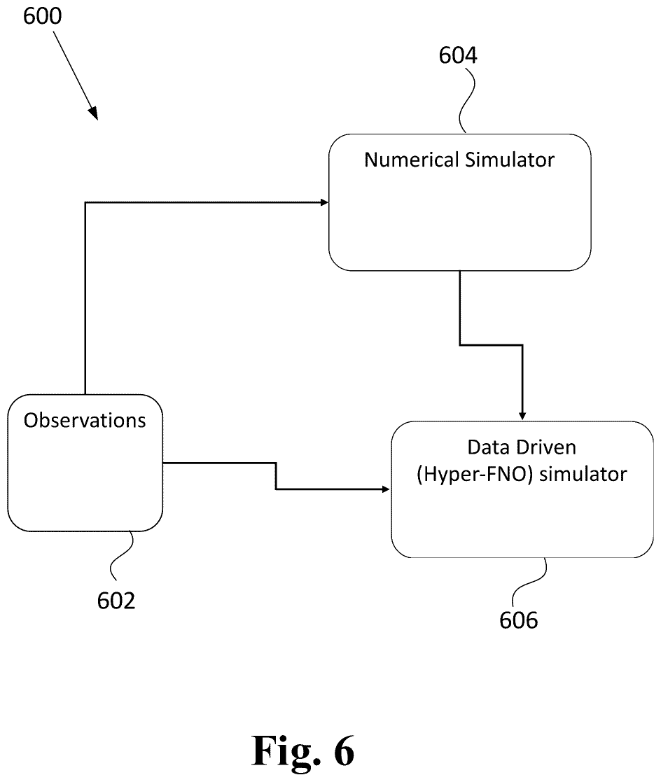

FIG. 6 illustrates a block diagram 600 of an interaction with a numerical simulator 604. The numerical simulator 604 is a machine learning model, which includes a main network that is trained via machine learning and, once fully trained, used to produce predictive data values or signals. The numerical simulator 604 is configured to receive observation data from observations 602. The hyper-FNO 606 is a data-driven simulator also configured to receive observation data from observations 602 as well as outputs from the numerical simulator 604.

In an exemplary implementation, numerical simulations may be used to provide molecular simulation for new materials and new protein discovery. In traditional approaches, a numerical simulator uses a model for molecular and atomic interactions at a small scale and produces a prediction based on these smaller-scale models. Small errors and/or un-modelled dynamics can lead to a prediction that is not in line with real world observations. However, in an aspect of the present disclosure, a hyper-FNO can be used within a machine learning model to model hyper-parameters of the numerical simulation and find the most appropriate configuration for the main network. In an embodiment, the hyper-FNO can also be trained on specific calibrated configuration and observational data, thereby predicting new outputs based on one or more new unseen configurations.

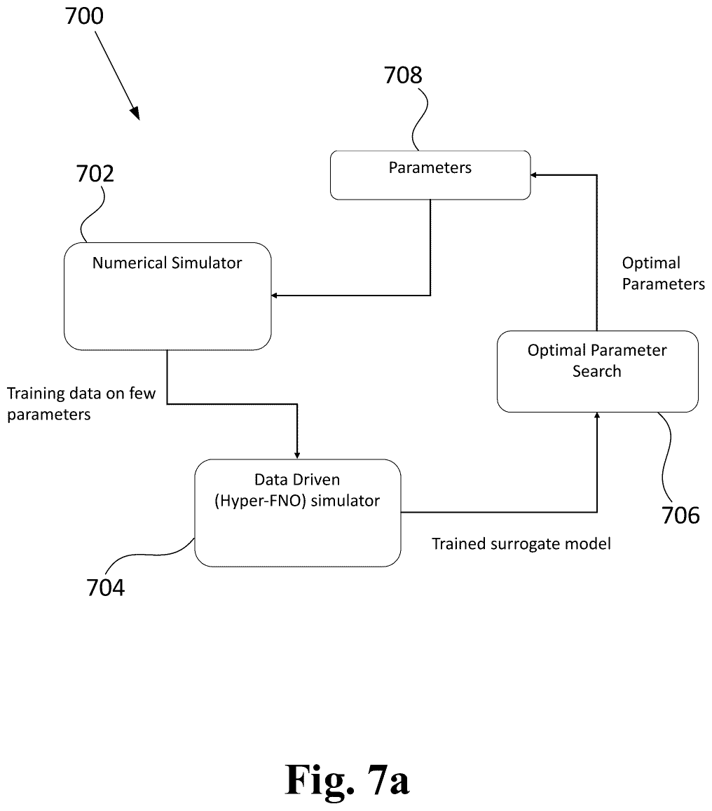

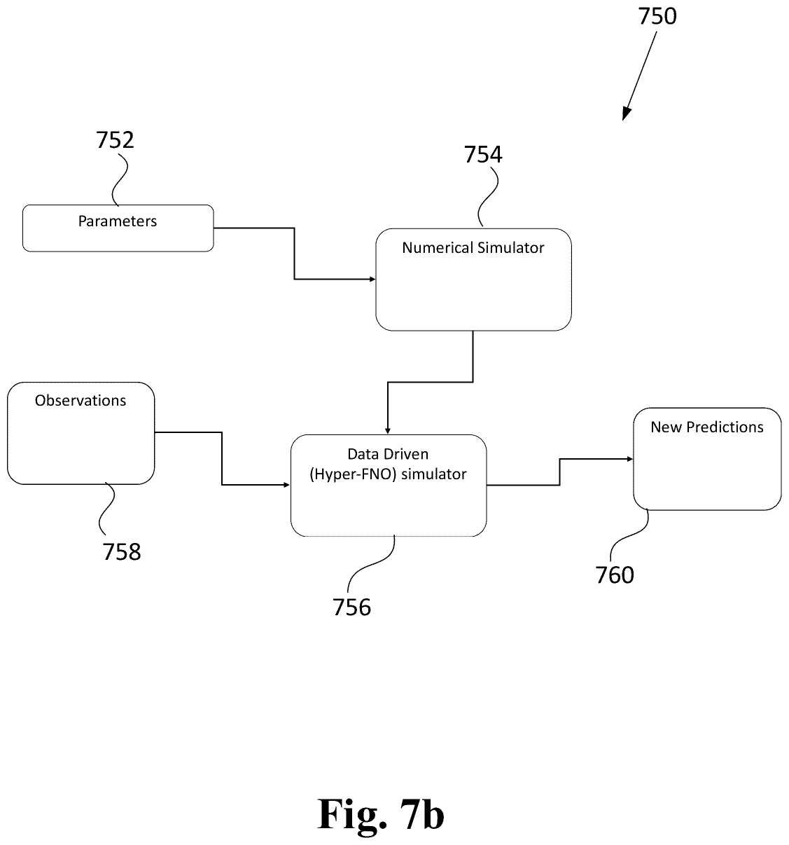

FIG. 7a illustrates a block diagram 700 of hyper parameter optimization for a numerical simulator 702. Specifically, the diagram 700 illustrates a loop in which the output of a numerical simulator 702 comprising training data on a few parameters is received by a hyper-FNO 704, which is configured to output a trained surrogate model to conduct an optimal parameter search 706. The optimal parameter search 706 outputs optimal parameters determined as a result of the search to parameters 708, which are configured to be received by the numerical simulator 702.

FIG. 7b illustrates a block diagram 750 of a hyper-FNO 756 configured to integrate simulation and observation for domain transfer. Parameters 752 are received by a numerical simulator 754 as inputs, and the numerical simulator 754 forwards output data to the hyper-FNO 756. The hyper-FNO 756 is also configured to receive as inputs observation data from observations 758. Using both the observation data and output data, the hyper-FNO outputs new predictions 760. The hyper-FNO 756 is data driven in that it outputs new predictions based on both numerical simulator 754 outputs and observational data.

In an exemplary implementation, numerical simulations may be used for identification of blood flow in arteries and vessels and/or identification of blood coagulation. In traditional approaches, blood flow can be modelled using a complex system of PDs, such as Navier-Stokes equations, representing flow over a network of arteries and vessels of the human body. In an embodiment of the present disclosure, a hyper-FNO is used to model the flow in each arterial section and to adapt the model to observational data. For example, the hyper-FNO may be used to adapt the model based on changes in the form of blood vessels, and to detect problems of artificial blood vessels before they are implanted or otherwise utilized in surgery.

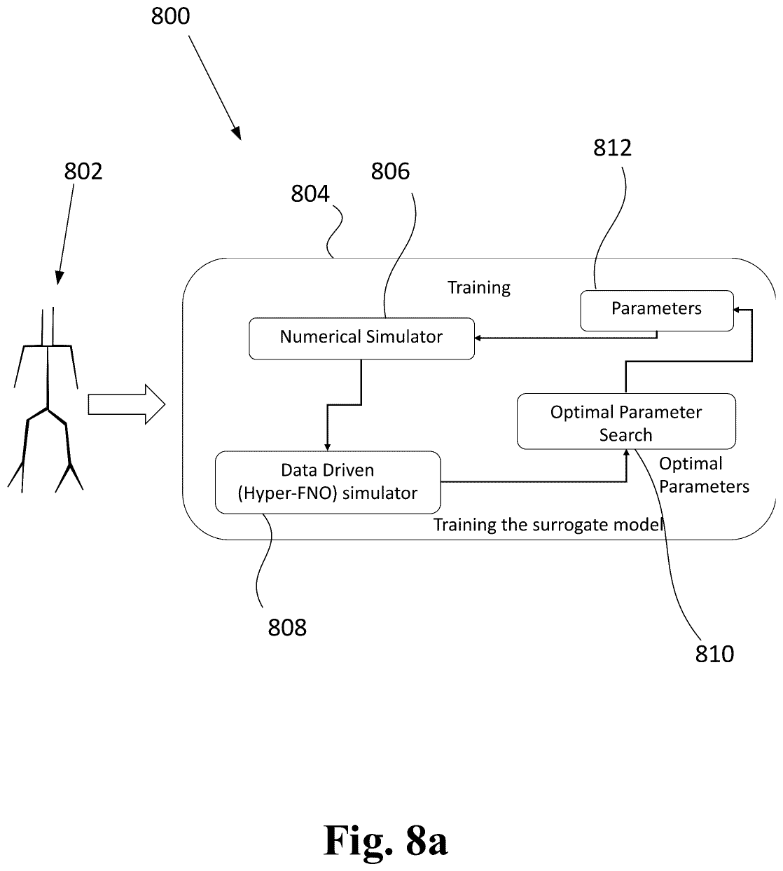

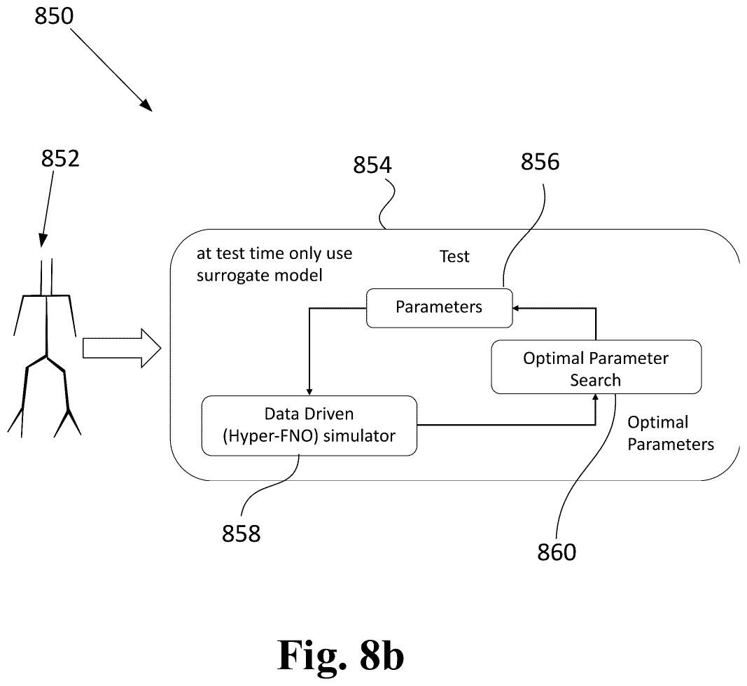

For example, FIG. 8a illustrates a training model 800 for blood flow modeling. During training, a training module 804 uses measured data from a specimen 802 and data from a numerical simulator 806 to train a surrogate model. In a similar manner to the system represented by the block diagram 700 of FIG. 7a, the training module 804 includes a numerical simulator 806, hyper-FNO 808, optimal parameter search 810, and parameters 812 in a looped configuration.

FIG. 8b illustrates a test model 850 for blood flow modeling. During testing, measurements from a specimen 852 are used with a surrogate model trained according to the model illustrated in FIG. 8a. The surrogate model is thus used to identify potential blood obstructions, blood flows, or other characteristics of the circulatory system of the specimen 852. The test model 850 includes a test module 854 that includes parameters 856, which are used by a hyper-FNO 858 to produce parameters, which are used for an optimal parameter search 860.

In an exemplary implementation, numerical simulations may be used for identification of gene regulatory networks from observational data. Gene regulatory networks describe the interaction, be it by promotion or inhibition, of gene activity, including the interactions between a gene and other genes, proteins, or other cell elements. Gene regulatory networks are used to model causal relationships among these elements. In traditional approaches, ordinary or partial differential equations can be used to describe such interactions. The final expression level of these interactions can be partially observed using different measurement techniques, such as gene sequencing.

In an embodiment of the present disclosure, observational data can be used to for model training and to derive the structure and parameters of the ordinary or partial differential equations used to describe gene regulatory networks. Derived models are used to detect changes in the gene regulatory network and to measure the consistency of a gene expression with a specific gene regulatory network, thereby aiding detection of results that are outside of a modeled statistical distribution.

In an exemplary implementation, numerical simulations may be used to solve inverse problems for water contamination and/or oil exploration. Traditional approaches describe propagation of pollution or of an acoustic wave with a PDE. In an aspect, a hyper-FNO and is used in conjunction with numerical simulation to estimate a propagation profile of pollutant or a wave.

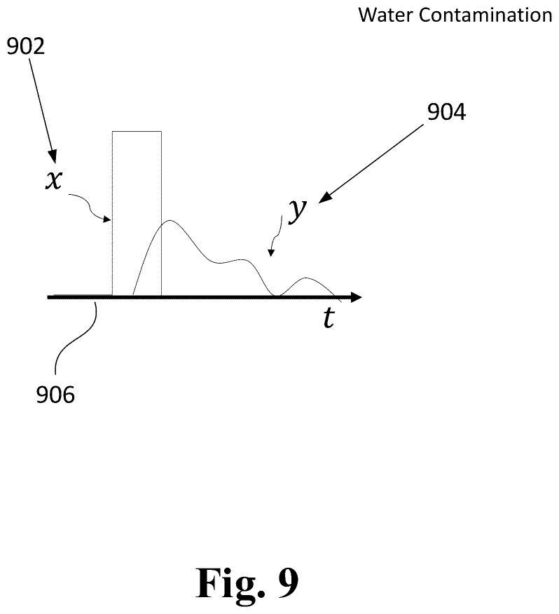

FIG. 9 illustrates water pollution simulation data. Because propagation of contamination and/or pollution in water can be approximated with the aid of PDEs, a hyper-FNO and numerical simulation as in above-described embodiments may be used to estimate a propagation profile or a wave. The position of a substance, which may include a contaminant or pollutant, is described by a first function (x(t)) 902 with respect to time 906, which represents the horizontal axis of the illustrated data. A downstream position (y(t)) 904 can be observed and parameterized, for example by the speed of the water in the observed system or the height/level of an observed river. Inverse problems relating to contaminant tracking and/or prediction can be more readily and efficiently solved by means of the foregoing aspects of the present disclosure.

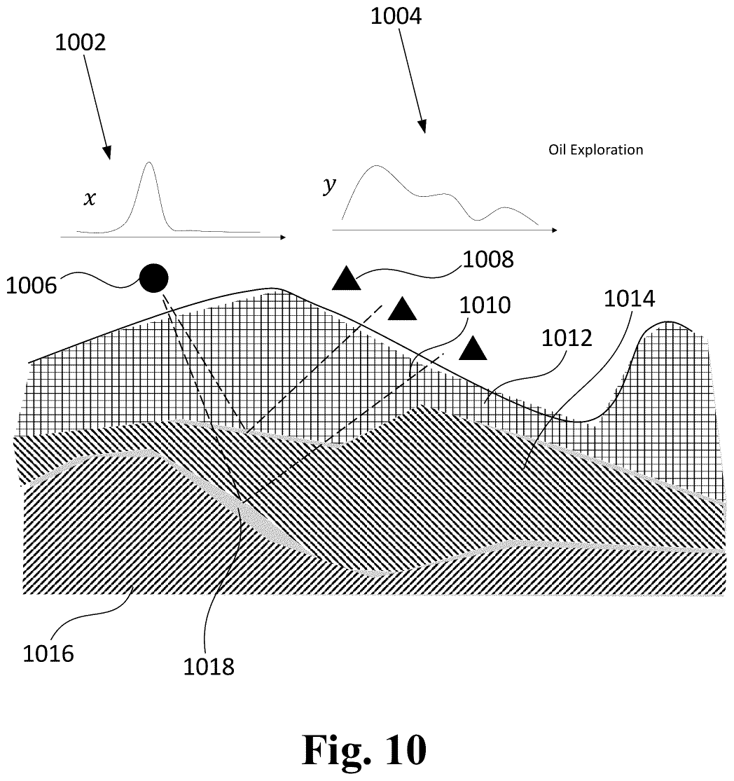

Likewise, a hyper-FNO can be used in conjunction with numerical simulation to estimate porosity and topology of a domain based on acoustic wave propagation. FIG. 10 illustrates oil exploration and simulation data. Observational data regarding a position of a sound wave (x) 1002 and the sound wave's propagation (y(t)) 1004 can be used to train a model in a simulated environment as then deployed in a real situation to predict sound wave propagation. In the illustrated embodiment, an emitter 1006 emits a sound wave 1010 that propagates through various geological features 1012, 1014, 1016, 1018 of varying composition and characteristics. Propagation of the sound wave 1010 may also be measured by one or more receivers 1008 configured to measure sound waves 1010 as they reflect from various geological features 1012, 1014, 1016, 1018. By using aspects of the present disclosure, observational data may be used to train a main network more efficiently, and thus aid in producing a main network that produces more accurate prediction data for oil exploration.

In an aspect of the present disclosure, the foregoing machine learning models are used in diagnostic applications such as, for example, pathology, to model progranulin (GRN) and/or neoantigen simulations. In some embodiments, digital twin simulation, whereby a virtual representation of an object or system that spans the object's lifecycle is created and updated using real-time data, is used and incorporates the foregoing numerical simulations and model creation methods. Such embodiments have significant advantages over traditional simulations and simulation methods, as a numerical simulation can be applied to a more specific population of people by adapting parameters for personalized treatment, which would otherwise be too time and/or resource intensive.

It will be readily appreciated that the foregoing simulation methods and machine learning models may also provide advantageous benefits when used and/or applied in a variety of fields or industries when combined with IPC solutions.

In some embodiments, it will be readily appreciated that the size of the main network (in terms of quantity of data, computational power required for execution, and/or memory usage) is smaller than that of a hyper network. In some embodiments, the presence of a hyper network may be determined based on a comparison of the size of the main network with the hyper network, thereby allowing a system to determine an association of a main network with a hyper network. It will be readily appreciated that a hyper network according to the above-described embodiments typically are larger than main networks due to their configuration to process and output parameters to the main network, which is generated based on parameter configurations set forth by the hyper network.

In some embodiments, a hyper network may be detected by checking if additional information as external parameter are used in a predictive model.

In some embodiments, a user interface (UI) is included in a simulation system or is displayed via instructions stored in a computer-readable medium. The user interface may display and/or allow for user input of parameters used as inputs by the hyper network. In some embodiments, user input is accomplished by manual entry and/or selection of parameters in the UI.

In connection with the foregoing aspects, further detail will be provided below regarding previously disclosed, additional, and/or related aspects of the present disclosure. Minor variations in wording and tone are not to be understood as delimiting aspects exclusively of one another. It will be readily understood that the presentation of the following disclosure, which includes formulas, data, and descriptions, elucidate aspects of the present disclosure. The following disclosure includes short form citations to references, a full list of corresponding long form citations of which are included in the List of References at the end of the disclosure herein.

As described previously, traditional FNO approaches modeling PDEs are not able to model a high variation of the parameters of some PDEs. To this end, hyper-FNO is an approach to extend FNOs using hyper networks so as to increase the models' extrapolation behavior to a wider range of PDE parameters using a single model. Hyper-FNO learns to generate the parameters of functions operating in both the original and the frequency domain. This architecture is evaluated using various simulation problems. The success of deep learning methods in various domains has recently been carried over to simulations of physical systems. For instance, neural networks are now commonly used to approximate the solution of a PDE or for approximating its Green's function (Thuerey, et al., 2021; Avrutskiy, 2020; Karniadakis, et al., 2021; Li, et al., 2021; Raissi, et al., 2019; Chen, et al., 2018; Raissi, 2018; Raissi, et al., 2018b). In applications such as vehicle aerodynamic design and prototyping, access to approximate solutions at a lower computation cost is often preferable over solutions with a known approximation error but prohibitive computational costs. In these contexts, machine learning models provide an approach to solving PDEs which complements traditional numerical solvers. Furthermore, data-driven methods are useful when observations are noisy or the underlying or the underlying physical model is not fully known or defined (Eivazi, et al., 2021; Tipireddy, et al., 2019).

Neural Operators (NOs) (Li, et al., 2020) and in particular Fourier Neural Operators (FNOs) (Guibas et al., 2021; Li, et al., 2021) have impressive performance and can be applied in challenging scenarios such as weather forecasting (Pathak et al., 2022). In contrast to physics informed neural networks (PINNs) (Raissi, et al., 2019), Neural Operators do not require the knowledge of the physical model and can be applied whenever observations are available. As such, Neural Operators are fully data-driven methods. Neural Operators, however, work under the assumption that the governing PDE is fixed, that is, its parameters are static while the initial condition is what changes. If this assumption is not met, the performances of these approaches deteriorate (Mischaikow and Mrozek, 1995). Thus, when the interest is in a situation that requires the evaluation over multiple physical model parametrizations, then (1) the Neural Operators for each of the parameter configurations should be re-trained, or (2) the parameter values should be included as input to the neural operator (Arthurs and King, 2021). Training over a large number of possible parametrizations is computationally demanding. On the other hand, increasing the number of parameters of the network increases the computational complexity of the model and would increase inference time, which takes away from the advantage surrogate models have over numerical solvers.

In the present disclosure, a meta-learning problem is formulated in which each possible set of parameter values of the PDE induces a separate task. At inference time, the learned meta-model is used to adapt to the current task, that is, the given inference time parameters of the PDE. A hyper-FNO is thus disclosed, as well as a method to adapt the Neural Operator over a wide range of parameter configurations, which uses hyper networks (Ha, et al., 2016a). Hyper-FNO learns to model the parameter space of a Green function operator that takes as input the parameters and produces as output the neural network that approximates the Green function operator associated with that parametrization. By separating the training and testing in two networks (the hyper network and the main network), complexity at inference time is reduced while maintaining the prediction power of the original model and without the need of a fine-tuning period.

A solution to a PDE is a vector valued function u: T×X×Λ on some spatial domain X and temporal index T, parameterized over Λ. For example, in the heat diffusion equation, u could represent the temperature in the room at a location x∈X at a time t∈T, where the conductivity field is defined by λ: X→ [symbol] . A forward operator maps the solution at one instant of time to a future time step F: v(t, x, λ)→v(t+1, x, λ). The forward operator is known, and the solution of the PDE for any time can be computed, given the initial conditions.

Thus, a general problem of learning a class of an operator, which includes the forward operator G^{λ}: A×Λ→U between two infinite dimensional spaces of functions A: [symbol] ^{d}→ [symbol] ^{p} and U: [symbol] R^{d}→ [symbol] ^{q}, on the space of parameters Λ, from a finite collection of observed data {λⱼ, aⱼ, uⱼ}ᵢ₌₁^{N}, λⱼ∈Λ, aⱼ∈A, uⱼ∈U, composed of parameter-input-output triplet. For the forward operator, aⱼ is the solution of a given PDE conditioned to the PDE parameter λⱼ at time t, while uⱼ is the solution at time t+1. The input aⱼ˜μ and the parameter λⱼ˜ρ are drown from two known probability distribution μ over A and ρ over Λ. To solve this problem, a family of operator G_{θ}^{λ}: A×Λ×Θ is considered, which minimizes

$${min}_{θ} {𝔼}_{a ∼ μ , λ ∼ ρ} ℒ ( {G}_{θ}^{λ} ( a ) , G ( a ) ) ,$$

with [symbol] (u′, u) being a cost function measuring the difference between the true and predicted output.

A diffusion equation with no boundary conditions and diffusion coefficient D is defined by:

uₜ(t,x)=Du_{xy}(y,x),t∈(0,1],x∈[−∞,∞]

u(t=0,x)=u₀(x),x∈[−∞,∞]

Where uₜ=∂u/∂t and uₓₓ=∂²/∂x², while u₀(x) is the initial condition. The general solution of this equation can be written using Green's function as:

$${u}_{t} ( t , x ) = {\int }_{- ∞}^{∞} \frac{1}{2 \sqrt{π Dt}} exp [ - \frac{{( x - y )}^{2}}{4 Dt} ] {u}_{0} ( y ) dy , \qquad ( 1 )$$

The convolution can now be written in the Fourier space as:

$$U ( t , ω ) = G ( T , ω ) U ( 0 , ω ) , G ( t , ω ) = \frac{1}{\sqrt{2 π}} {e}^{- 4 {ω}^{2} Dt} \qquad ( 2 )$$

where U(t, ω) and G(T, ω) are the solution and the Green operator in the Fourier space. The relation

$${F}_{ω} ( {e}^{- {ax}^{2}} ) = \frac{{e}^{- \frac{{ω}^{2}}{4 a}}}{\sqrt{2 a}}$$

is used when performing the Fourier transformation. For a small change of Dt→Dt+ΔDt, the change in Green's function is given by:

∂_{Dt}G(t,ω)=−4ω²G(t,ω).

Thus, Green's function can be written as a function of the change in the parameters ΔDt as:

G(T,ω)+∂_{Dt}G(t,ω)ΔDt=H(ω,z,Δz)G(t,ω), (3)

H(ω,z,Δz)=1−4ω²Δz, (4)

where z≡Dt. This means that when the parameters of the diffusion equation are updated, the Green's function operator is multiplied by a function H(ω, z, Δz) in Fourier space, where H(ω, z, Δz) is linear in the change of parameters Δz. The advantage of doing this in the frequency domain is that the function could be more compactly written Indeed, few frequencies are typically necessary to describe the behavior of Green's function.

Furthermore, the rate of change of the solution can be found as a function of the change in the PDE parameter. First, the difference between the original solution and the solution after the infinitesimal change Δλ, which is

∫_{T,Ω}∥U′(t,ω)−U(t,ω)∥dtdω=|Δλ|∫_{T,Ω}∥4ω²tG(t,ω)U(0,ω)∥dtdω (5)

with U′(t, ω)=(G(t, ω)+∂_{λ}G(t, ω)Δλ)U(0, ω). For Δλ≠0, the difference increases with the square of the frequency. The implication is that if the parameter of the equation is changed, a change in frequency is induced that is proportional to |Δλ|∫_{T,Ω}∥4ω²tG(t, ω)U(0, ω)∥dtdω. The original operator thus is not more able to accurately predict the function at a later time, accumulating an error in time or frequency.

Interestingly, Green's function can also be implemented in the spatial domain, that is, the original, non-Fourier space, directly using Equation (1) and a convolutional neural network. Similarly to Fourier space, the variation of the Green function around the current parameters can be derived by considering that from Equation (1),

$$u ( t , x ) = f ( t , x ) {*}_{x} u ( 0 , x ) , f ( t , x ) = \frac{1}{2 \sqrt{π λ t}} {e}^{- \frac{{x}^{2}}{4 λ t}} \qquad ( 6 )$$

Where * is the convolution operator and then using the Taylor expansion

$$f ( t , x ) + {\partial }_{λ} f ( t , x ) Δ λ = h ( x , t , λ , Δ λ ) f ( t , x ) , \qquad ( 7 )$$

$$h ( x , t , λ , Δ λ ) = [ 1 + \frac{1}{λ} Δ λ \frac{{x}^{2}}{4 {λ}^{2} t} Δ λ ] . \qquad ( 8 )$$

In the spatial domain, the change of Green's function with respect to the change in parameters can be described as the multiplication of the base function by a term that corresponds to the variation of the parameters. While the two approaches are mathematically equivalent, one might provide a more suitable inductive bias in the context of learning surrogate models. Moreover, the specific implementation, for example, the discretization of the domain, might also affect the final performance. This motivates a goal to generate the parameters of linear transformations either in the frequency or spatial domain, or both.

A hyper-FNO formula can be derived with the help of the finite volume method. First, a general form of the field equation may be considered with parameters:

∂ₜU(x,t)+∂ₓ[F(x,t)+αG(x,t)]=βS(x,t), (9)

where the equation depends linearly on the parameters: α and β. Assuming the finite volume method is used, Equation (9) reduces to:

$${U}_{j}^{n + 1} = {U}_{j}^{n} - \frac{Δ t}{Δ x} ( {F}_{j + \frac{1}{2}}^{n + \frac{1}{2}} - {F}_{j - \frac{1}{2}}^{n + \frac{1}{2}} ) - α \frac{Δ t}{Δ x} ( {G}_{j + \frac{1}{2}}^{n + \frac{1}{2}} - {G}_{j - \frac{1}{2}}^{n + \frac{1}{2}} ) + β Δ {tS}_{j}^{n + \frac{1}{2}} , \qquad ( 10 )$$

where subscripts n, j are time-step and cell number, respectively, and j±½ means the cell boundaries. Δt, Δx is the time-step and cell size, respectively. The above equation shows that the effect of parameter value change always linearly depends on the parameter in the case of the finite volume method. This is true when Δt, Δx<1.

On the other hand, in the case of a machine learning model, the above equation becomes:

Uⱼⁿ⁺¹= [symbol] (Uⁿ;α,β). (11)

Because of the flexibility of a deep neural network (DNN), there is a vast amount of the degree of freedom to take into account the parameter information into the DNN. Here, it is natural for machine learning models to take into account parameter dependence as in Equation (10):

Uⱼⁿ⁺¹= [symbol] (Uⁿ)+α [symbol] (Uⁿ)+β [symbol] )(Uⁿ). (12)

What follows is a 1-layer model that can be rewritten as:

Uⱼⁿ⁺¹=σ[(W_{F}+αW_{G}+βW_{S})Uⁿ]. (13)

This is equivalent to the hyper-FNO formula.

Equation (10) is valid independent of the absolute value of parameters α, β but depends on Δx, Δt. Hence, Equation (13) is also valid when Δx, Δt<1.

In Equation (6), the convolution function of the spatial representation of the Green's function has infinite domain and its effective width is proportional to λ. When implemented using a finite convolution kernel, as in the disclosed machine learning frameworks, the convolution function is truncated and the distortion of the operation increases with the increase of λ. On the other side, in Equation (2), the Green's function in the frequency domain, while still affected by the parameter λ, is multiplied in frequency by the initial condition function. When the initial condition is limited in frequency, the distortion introduced by the frequency discretization and limit, as introduced in the FNO model, is less severe. Thus, even if change in the parameter in both spatial and frequency domain can be modeled, the latter could be more powerful and easier to model.

FNOs (Guibas, et al., 2021; Li, et al., 2021) are composed of initial and final projection networks parameterized by P and Q, Q′. These two networks transform the input signal into a latent space, adding and reducing features at each spatial location. After the initial feature expansion through a projection, the FNOs consists of blocks of Fourier layers which consist of two parallel spatial and frequency layers. The spatial layer, parameterized by a tensor W, is implemented using a 1-d convolutional network. The frequency layer is parameterized by a tensor R and operates in Fourier space. The prior transformation to Fourier space is implemented using the Fast Fourier Transform (FFT, F)

z^{l+1}=σ(W^{l}z^{l}+F⁻¹(R^{l}F(z^{l}))), (14)

z⁰=Px,u=Q′σ(Qz^{L-1}) (15)

Where the projection is implemented using two consecutive fully connected layers. Since the FNO is operating in both frequency and spatial domains, for the purpose of this disclosure, the former is called the Fourier domain, and the latter the spatial domain (or original domain). In Equation (14) and Equation (15), the variables z, x, u are in the spatial domain.

Hyper networks (Ha, et al., 2016) are a meta-learning method comprised of two networks: the main and the hyper network. The main network, with parameters Ø, is used during inference and the training is performed on θ, the parameters of the hyper network. The hyper network is trained to generate the parameters Ø of the main network. Hence, the parameters θ are generated through the hyper network as Ø=h(θ, λ), where λ are the hyper-parameters. Typically, the hyper network generates all parameters of the main network. In this work, a hyper network is used to generate the weights of particular subnetworks of the main network.

The hyper-FNO network is built by a hyper network that produces the parameters for the main network, where the main network is an instance of the FNO architecture. If FNO is written as the function ƒ(φ, x), then the hyper-FNO can be written as:

Ø=h(θ,λ),û=ƒ(φ,x)

where û is the predicted solution given the PDE of parameters λ and initial condition x, while φ are the parameters of main network parameters, which are generated by the hyper network. The hyper network has parameters θ and are learned end-to-end. The hyper network is trained by minimizing the loss function

L(θ)= [symbol] _{λ˜p(λ)}L_{λ}^{tr}(θ,λ),

where L_{λ}(θ,λ)= [symbol] _{(x,u)˜D}_{_{λ}}_{^{tr}}∥u−ƒ(φ_{λ},x)∥²

and φ_{λ}=h(θ,λ).

Hyper Networks are used to generate the parameters of the main network, where the parameters are specific for the current task. In the typical scenario, the hyper network is a large network that produces a smaller network. In this way the complexity of adaptation is off-loaded to the hyper network, while the prediction is performed by the smaller main network. This approach is particular convenient in order to reduce the computation complexity of the prediction, for example in case of limited resources at inference time. An alternative approach aims at using a hyper network that only marginally increases the size of the main network, but still allow to easily adapt to new tasks. This second scenario can have a special class of hyper layer, which then can modularly build the main network.

In hyper-FNO, each layer of the FNO is generated by an Hyper Fourier Layer (HyperFL), and used in the main Fourier Layer as

z^{l+1}=σ(z^{l}+W_{U}_{^{l}}(λ)z^{l}+F⁻¹(R_{V}_{^{l}}(λ)F(z^{l})))

z⁰=P(λ)x,u=Q′(λ)σ(Q(λ)z^{L-1})

where the hyper network generates (1) reference to the annex on the example of diffusion; (2) in a more simple case, only a scaling quantity; and (3) in a case where change with different strength and frequency or convolution is desired, then a change in equation with the parameters as

R_{V}_{^{l}}(λ)=R₀^{l}+(V₀^{l}λ,V₁^{l}λ,V₂^{l}λ)⊙_{row,col,depth}R₁^{l}, (16)

W_{U}_{^{l}}(λ)=W₀^{l}+(U₀^{l}λ,U₁^{l}λ)⊙_{row,col}W₁^{l} (17)

where ⊙_{row,col}, ⊙_{row,col,depth} represents the Hadamard product applied to the rows, columns, and depths of tensor, using vectors whose size is equal to the number of rows, columns, and depths, respectively.

This version is called the Addition version. In addition, U^{l}=(U₀^{l}, U₁^{l}) and V^{l}=(V₀^{l}, V₁^{l}, V₂^{l}) are the parameters of the spatial and frequency tensors. The number of parameters of Equation (16) are about twice the number of parameters of the main network. In order to reduce the number of parameters, another formulation (multiplicative) that significantly reduces the number of parameters may be used. This choice is justified by the shape of the Taylor expansion. The parameters of the main network are generated by

Rᵥ_{^{l}}(λ)=rᵢⱼₘₗ^{FT}=rᵢⱼₘ^{0l}(1+λₖv₀^{ikl},v₁^{jkl}v₂^{mkl}) (18)

W_{U}_{^{l}}(λ)=wᵢⱼₗ^{XT}=wᵢⱼ^{0l}(1+λₖu₀^{ikl}u₁^{jkl}), (19)

where rᵢⱼₘ^{FT} and wᵢⱼₗ^{XT} are the frequency and spatial tensors used in the main network, written using the Einstein notation. This is called the Taylor version. Also the initial expansion and final projection are generated by the hyper network using

P_{V}(λ)=P₀+(V₀λ,V₁λ)⊙_{row,col}P₁, (20)

Q_{U}(λ)=Q₀+(U₀λ,U₁λ)⊙_{row,col}Q₁, (21)

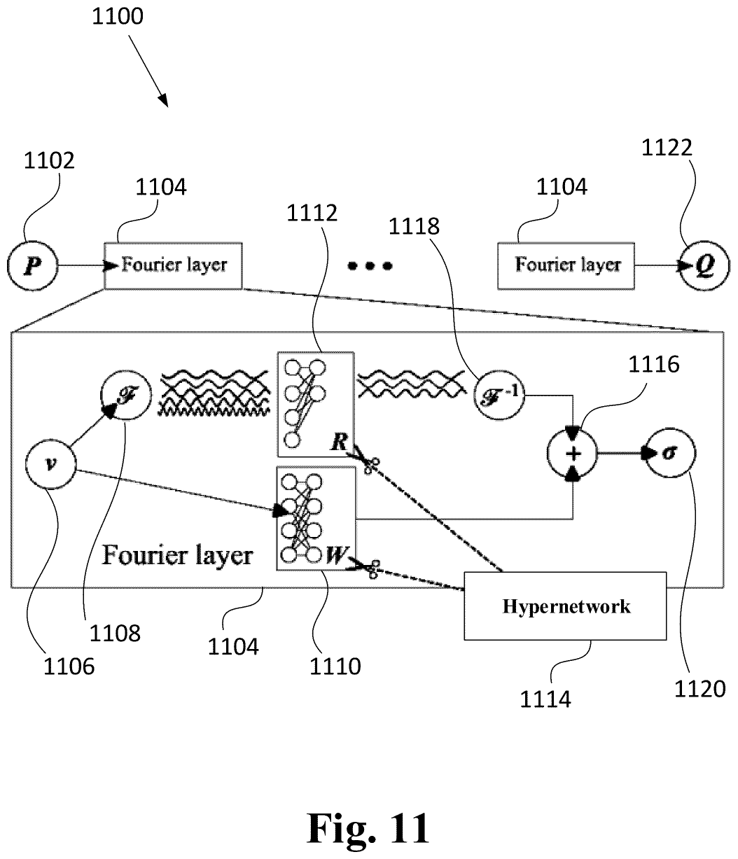

The parameters λ can be encoded using an additional neural networks of minimal size, λ′=g(T, λ), with T additional hyper-FNO parameters. The parameters of the hyper-FNO are θ={Vₗ, Uₗ, Rₗ, Wₗ, T}_{l=0,L-1}, where Rₗ, Wₗ, depending by the architecture choice, may contain one or two tensors. FIG. 11 illustrates a hyper-FNO 1100 that includes a vase neural operator architecture and a hyper network 1114. The hyper-FNO 1100 includes an initial projection network 1102 with parameter P and a final projection network 1122 with parameter Q. The two projection networks 1102, 1122 transform an input signal into a latent space, adding and reducing features at each spatial location. The initial projection network 1102 is transformed by a Fourier layer 1104, which includes two parallel layers, a frequency layer 1112 parameterized by a tensor R and a spatial layer 1110 parameterized by a tensor W. The transformation of data 1106 occurs via a Fourier Transform 1106. A hyper network 1114 generates, for each layer of a base network and depending on the configuration, the frequency and/or spatial weight matrices R_{V}^{l}(λ) and W_{U}^{l}(λ). An output of the frequency layer 1112 is transformed via an inverse Fourier Transform 1118 and output to a layer combiner 1116. The layer combiner also receives an output of the spatial layer 1110 and combines received data to an output 1120.

Equation (14) can be differentiated with respect to the parameter λ, leading to an identity

∇_{λ}z^{l+1}∇_{λ}Wz^{l}+W∇_{λ}z^{l}+ [symbol] ⁻¹(∇_{λ}R [symbol] (z^{l}))+ [symbol] ⁻¹(R [symbol] (∇_{λ}z^{l})),

where the two terms ∇_{λ}W and V_{λ}R are the variation of the FNO parameters. In one approach,

∇_{λ}R_{V}_{^{l}}(λ)=(V₀^{l},V₁^{l},V₂^{l})⊙_{row,col,depth}R₁^{l}, (22)

∇_{λ}W_{U}_{^{l}}(λ)=(U₀^{l},U₁^{l})⊙_{row,col}W₁^{l} (23)

where the change is a linear transformation in the parameter λ.

The extension of new operators in the Fourier and spatial domain may also be considered. Specifically, the various families of operations, in particular affine, rotation, polynomial, multilayer perceptron (MLP), and rank-1 operations may be considered. The generic operator is described as

Y=T′(λ′,X),λ′=ƒ_{θ}(λ) (24)

where Y is any of the FNO parameters R, W, P, Q, and X is the hyper-parameter. ƒ_{θ} is a generic transformation used to increase or reduce the number of parameters or to include non-linear transformations.

The first class can be written in the following ways using Einstein notation:

T(λ,X)=yᵢⱼₘₗ=xᵢⱼₘ^{0l}+xᵢⱼₘ^{1l}λₖx₀^{ikl}x₁^{jkl}x₂^{mkl}) (25)

T(λ,X)=yᵢⱼₘₗ=xᵢⱼₘ^{0l}(1+λₖx₀^{ikl}x₁^{jkl}x₂^{mkl}) (26)

For the rotation, the exponential operator may be used. Since a tensor is included, the exponential map of a tensor can be defined as

$$exp \{ X \} = {\sum }_{n = 0}^{∞} \frac{1}{n} {X}^{n} .$$

A rotation can then be written as exp{λX}. In order to restrict the number of parameters and the complexity, the Rodrigues's formula

$$exp \{ X \} = I + \frac{sin λ}{λ} X + \frac{1 - cos λ}{{λ}^{2}} X$$

with X being an anti-symmetric tensor (for a matrix, it is X=AB−BA, for tensor X=½(X_{. . . ij . . .} −X_{. . . ji . . .} ), thus leading to the rotation (exponentiation) transformation as:

$$T ( λ , X ) = {\prod }_{k} exp \{ {λ}_{k} {X}_{0}^{k} \} {X}_{1} = {\prod }_{k} ( I + \frac{sin {λ}_{k}}{{α}_{k}} {X}_{0 , k} + \frac{1 - cos {λ}_{k}}{{α}_{k}^{2}} {X}_{0 , k}^{2} ) {X}_{1} , \qquad ( 27 )$$

with X_{0,k}, X₁ being learnable parameters and the product with λ being implementable in a similar manner as in Equation (25), while αₖ=∥X_{0,k}∥.

An alternative is to use a polynomial over the tensor X:

T(λ,X)=poly_{λ}(X)=Σₙ₌₀^{N}λₙXⁿ, (28)

where Xⁿ is the n times application of X.

The most generic transformation is implemented using a standard MLP, in which

Y=gₓ(λ), (29)

where gₓ is an MLP with parameters X.

The rotation and polynomial operators are expensive in terms of number of parameters, since they require full rank operators. For example, rotations are inevitable matrices, while the power operator will produce equal but scalar scaled matrices, i.e. (vv^{T})ⁿ=(v^{T}v)ⁿvv^{T}, when applied to rank-1 matrices. Thus, the use of rank-1 updates is considered wherein for each parameter λₖ, a rank-1 vector transformation can be written in simplified form as:

Y=Πₖ(I+λₖx₀^{k}x₀^{kT})X₁, (30)

where x₀^{k}, X₁ are trainable parameters.

In the effort of identifying nonlinear dynamical systems from data, the Multi Step neural networks (Raissi, et al., 2018) uses the multi-step time-stepping schemes to learn the system dynamics. The PDE is expanded in the time dimension and expressed as a M step equation, where the step hyper-parameters α, β define the scheme, while the system dynamic is capture by the neural network ƒ, whose parameters are learnt by minimizing the mean square error with the observed data. This approach is thus limited to time-series data.

HyperPINN (Belbute-Peres, et al., 2021), a closely related work, introduce the use of hyper network for Physics Informed Neural Networks (PINNs). An hyper network generates the main network that is then used to solve the specific PDE. This approach inherit the same limitations of the PINNS, and thus requires to run multiple iteration for each new initial conditions, thus requiring relatively long inference time.

Meta-learning (Chen, et al., 2019) has been used to help solving advection-diffusion-reaction (ADR) equations to optimize for the hyper-parameters of sPINN (O'Leary, et al., 2021), the stochastic version of PINN, using Bayesian optimization that uses the composite multi-fidelity neural network proposed in (Meng and Karniadakis, 2020). This approach allows to estimate the PDE parameters and reduce the computation time, but it still requires multiple evaluation for every new initial condition, thus sharing similar limitations of PINNs, where the closed form equation of the problem is known in advance.

In order to evaluate the performance of hyper-FNO, the following problems are considered: 1) one-dimensional Burgers' equation, 2) one-dimensional reaction-diffusion equation, 3) two-dimensional Decaying Flow problem. Contrary to (Li, et al., 2021), datasets allowing various parameter values are prepared, for instance for the diffusion coefficient.

The resource costs of hyper-FNO is evaluated in terms of additional parameters needed by the respective architecture since each choice has a varying impact on the number of parameters. Indeed, the number of parameters defines the memory and computational complexity of the resulting neural network. The Taylor version only adds a negligible number of parameters and thus its complexity is similar to the original network. If an Addition version is used, the number of parameters doubles, while the full connected version does not have any upper bound. In experiments, a full connected network is used that leads to an increase up to 9 and 10 times the original parameters numbers. The computational complexity of the Addition and Taylor versions is thus equal to the original network.

Further reduction of complexity could be achieved when a reduced rank representation of the model tensors is used, for example one could model R₀^{l}=M₀^{l}N₀^{l}, with ρ(M₀^{l})=ρ(N₀^{l})<<ρ(R₀^{l}).

To illustrate the computational complexity of numerical simulators, the necessary computational cost of the traditional numerical solver for the field equations, such as hydrodynamic equations, may be considered. For simplicity, only the case of the explicit method is considered. First, the memory cost is approximately proportional to O(n_{c}N^{d}) where ne is the number of variables, Nis the resolution in a direction, and d is the number of dimensions along each axis. If using a method with n-th order temporal accuracy, the cost increases as: O(n n_{c}N^{d}) because n increments need to be performed. Such is the case, for example, using an n-th order Runge-Kutta method. Next, the necessary number of calculations is considered. Approximately speaking, the number of calculations is proportional to the mesh size, i.e. O(N^{d}). Assuming the advection equation, the stability condition, known as Courant-Friedrich-Lewy (CFL) condition, demands the upper limit of the time-step size should be: Δt∂Δx where Δt, Δx are the time-step size and mesh size, respectively. Hence, the necessary temporal step number is T_{fin}/Δt∂N where T_{fin} is the final time so that the total number of calculations is proportional to O(N^{d+1}). If the diffusion process is included, the CFL condition becomes Δt∂Δx², and the total number of calculations is proportional to O(N^{d+2}) when λt_{diff}/λt_{adv}=v_{c}λx/η<1 where v_{c} is the characteristic velocity, and l is the diffusion coefficient. This analysis shows that hyper-FNO becomes especially more effective than the direct numerical simulation when considering large diffusion coefficient and high-resolution cases, because the numerical complexity of hyper-FNO is independent of diffusion coefficient, and accuracy depends on the resolution very weakly, as shown in (Li, et al., 2021).

In Zero-Shot learning, at training time, access to solutions of a PDE over different initial conditions and for a set of PDE parameters is provided. At inference time, the PDE parameters of the new environment are used as inputs to the hyper-FNO to generate the parameters of the main FNO network. This network is then used to predict the solutions for new initial conditions. To evaluate the performance of hyper-FNO, it can be compared in various numerical computational problems against the original FNO (Li, et al., 2020) and the U-Net (Ronneberger, et al., 2015).

In addition to few-shot learning, a case may be considered wherein a set of training samples for a new environment are given which correspond to a new parameter configuration of the PDE. In this case, the parameters of the new environment are used to generate the FNO main network and the network is further trained with additional samples. Finally, the fine-tuned network is tested with test samples. An additional case may be considered wherein the parameters of each environment are assumed and not known, but the method will estimate the parameters based on held out validation samples. The problem to be solved can be written as a bi-level problem:

$${min}_{θ} {𝔼}_{e \sim p ( e )} {L}_{e}^{tr} ( θ , {λ}_{e} ) s . t . {λ}_{e} = arg {min}_{λ} {L}_{e}^{te} ( θ , λ ) . \qquad ( 31 )$$

At test time, some samples are used to predict the parameter of the dataset

$${λ}_{e} = arg {min}_{λ} L ( θ , {D}_{e}^{te} ) ,$$

then a query of the hyper-FNO is used to obtain the main network parameters Øₑ=h(θ, λₑ) and used to predict the solution to a PDE û=ƒ(Øₑ, x). The loss functions are defined for each environment

Lₑ^{tr}(θ,λ)= [symbol] _{(x,u)˜D}_{ₑ}_{^{tr}}∥u−ƒ(φ_{λ},x)∥²,

Lₑ^{tr}(θ,λ)= [symbol] _{(x,u)˜D}_{ₑ}_{^{te}}∥u−ƒ(φ^{λ},x)∥²,

respectively.

Meta-learning is the problem of learning meta-learning parameters from the source tasks in a way that helps learning a model for a target task. Each task is defined by two sets of samples: training and test samples. During training, the training sample from the source tasks can be used to learn the meta-model and use the test samples (or validation samples) to train the model.

$${min}_{θ} {𝔼}_{τ \sim {p}^{source} ( τ )} {L}_{τ}^{tr} ( θ , {λ}_{τ} ) s . t . {λ}_{τ} ( θ ) = arg {min}_{λ} {L}_{e}^{te} ( θ , λ ) . \qquad ( 32 )$$

The vector λ=[λ_{τ}]_{τ=1}^{T}, is defined, then the equations L(λ, θ)= [symbol] _{τ˜p}_{^{source}}_{(τ)}L_{τ}^{tr}/(θ, λ_{τ}) and E(λ, θ)= [symbol] _{τ˜p}_{^{source}}_{(τ)}L_{τ}^{te}(θ, λ_{τ}) are defined. Then, a gradient with respect to the parameters of the hyper-FNO can be written as:

d_{θ}L(λ,θ)|_{λ=λ*(θ)}=∇_{θ}L(λ,θ)|_{λ=λ*(θ)} (33)

−∇_{0,λ}_{^{T}}E(λ,θ)∇_{λ,λ}_{^{T}}⁻¹E(λ,θ)∇_{λ}L(λ,θ)|_{λ=λ*(θ)} (34)

The gradient can either be implemented directly or using an iterative loop, where the external loop looks for the parameter λ_{τ} associated with the environment, while the inner loop is solved for the hyper-FNO parameters. It is observed that the size of ∇_{λ}L(λ, θ) is proportional to the number of tasks and the dimensions for the PDE parameter representation. This dimension is typically low and during training is limited to the batch size, where a limited number of tasks are sampled. The inverse ∇_{λ,λ}_{^{T}}⁻¹(λ, θ) is not explicitly solved, but uses the vector-Jacobian trick, i.e. solving for x in a linear problem Ax=b, with A=∇_{λ,λ}_{^{T}}E(λ, θ) and b=∇_{λ}L(λ, θ).

The previous results follow based on the publications by Domke, which provides that the gradient of the loss function

$$L ( ω ) = l ( {y}^{*} ( ω ) ) s . t . {y}^{*} ( ω ) = arg {min}_{y} E ( y , ω ) \qquad ( 35 )$$

which is given by

d_{ω}L(ω)=d_{ω}l−∂_{ω}∂_{y}_{^{T}}E(y*(ω),ω)(∂_{y}∂_{y}_{^{T}}E(y*(ω),ω))⁻¹d_{y}l (36)

where the first term is present, and wherein 1 depends explicitly from ω, ie.e l(y, ω). (Domke, 2012).

At test time, new target tasks D_{τ} are used. For each task, a set D_{τ}^{tr} can be used to train the meta-model and adapt to a specific task. The performance on the D_{τ}^{te} of the target tasks can then be measured.

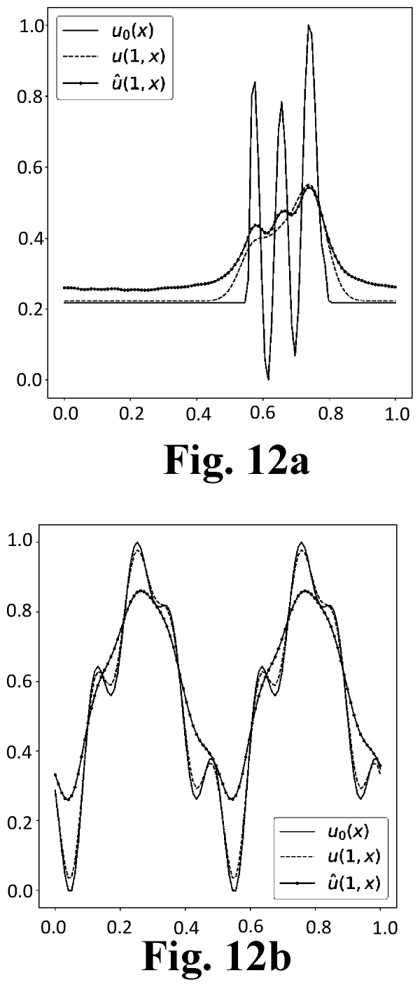

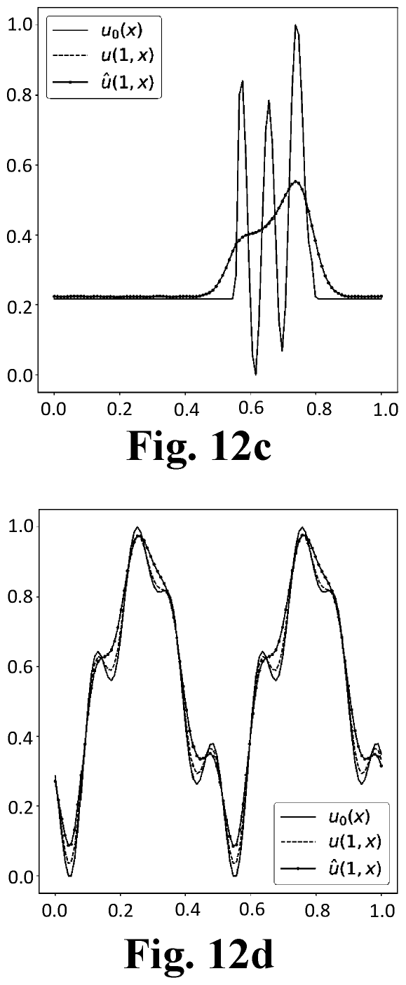

FIGS. 12(a)-12(b) illustrate a visual comparison of FNO and hyper-FNO for different initial conditions and PDE parameters.

TABLE 1
Burgers equations. Experiments averaged over 3 seeds.
A total of 100 tasks and split of training and testing
of 60/40 and the time horizon t = [5].

| Model | train_mse | test_mse | train l₂ | test l₂ |
|---|---|---|---|---|
| U-Net1d | 1.36e−02 | 1.38e−02 | 1.16e+00 | 1.13e+00 |
| FNO | 3.59e−05 | 1.20e−04 | 3.36e−02 | 1.02e−01 |
| Hyper-FNO | 3.06e−05 | 1.18e−04 | 3.11e−02 | 1.01e−01 |

TABLE 2
Burgers equations. Experiments averaged over 3 seeds.
A total of 100 tasks and split of training and testing
of 60/40 and the time horizon t = [10].

| Model | train MSE | test MSE | train l₂ | test l₂ |
|---|---|---|---|---|
| U-Net1d | 9.37e−03 | 9.32e−03 | 6.85e−01 | 6.75e−01 |
| FNO | 6.96e−04 | 1.02e−04 | 1.87e−01 | 7.38e−02 |
| Hyper-FNO | 2.14e−06 | 1.31e−05 | 3.26e−03 | 1.87e−02 |

TABLE 3
Experiments on the reaction-diffusion equation,
with time horizon t = [5].

| Model | train MSE | test MSE | train l₂ | test l₂ |
|---|---|---|---|---|
| U-Net1d | 9.51e−03 | 9.49e−03 | 6.95e−01 | 6.85e−01 |
| FNO | 1.15e−03 | 1.19e−03 | 1.90e−01 | 2.41e−01 |
| Hyper-FNO | 9.71e−07 | 1.11e−04 | 1.90e−03 | 5.36e−02 |

TABLE 4
Experiments on the reaction-diffusion equation,
with time horizon t = [10].

| Model | train MSE | test MSE | train l₂ | test l₂ |
|---|---|---|---|---|
| U-Net1d | 9.51e−03 | 9.49e−03 | 6.95e−01 | 6.85e−01 |
| FNO | 1.18e−03 | 1.20e−03 | 1.94e−01 | 2.43e−01 |
| Hyper-FNO | 9.44e−07 | 1.30e−04 | 1.86e−03 | 5.97e−02 |

The Burgers' equation is a PDE modeling the non-linear behavior and diffusion process of fluid dynamics as:

$${\partial }_{t} u ( t , x ) + {\partial }_{x} ( \frac{{u}^{2} ( t , x )}{2} ) = v {\partial }_{xx} u ( t , x ) , x ∈ ( 0 , 1 ) , t ∈ ( 0 , 1 ] , \qquad ( 37 )$$

$$u ( 0 , x ) = {u}_{0} ( x ) , x ∈ ( 0 , 1 ) . \qquad \text{(38)}$$

In an exemplary dataset, the dataset consists of 10,000 initial conditions of various distributions. The dataset is tested over two time horizons (t is also used to indicate the time step of the simulation) (t=[5, 10]). Table 1 and Table 2 show performance on the Burgers datasets. As observed in the results, the largest gain is obtained with the longest horizon. This is due to the effect of the parameter change. Close to the initial condition, the change in the solution as a function of the PDE parameters is relatively small. Similarly, for a very large horizon, the solution difference is also small, because of the source term that forces the system to be a steady-state independent of the initial condition, so the effect of the parameter change is negligible; while for an intermediate time horizon, the change is more evident and Hyper-FNO has the largest advantage. In FIG. 2, the effect of using Hyper-FNO on the solution of the Burgers equation of two initial conditions is visualized. Note that even in the training data, FNO loses the ability to predict the solution, when multiple parameters are considered.

Next consider a one-dimensional reaction-diffusion type PDE is considered that combines a diffusion process and a rapid evolution from a source term (Krishnapriyan, et al., 2021). The equation is expressed as:

∂ₜu(t,x)−v∂ₓₓu(t,x)−ρu(1−u)=0,x∈(0,1),t∈(0,1], (39)

u(0,x)=u₀(x),x∈(0,1). (40)

Tables 3 and 4 show the results of the Hyper-FNO on the reaction-diffusion dataset for time horizon t=[5, 10]. Similar to the Burgers equation, also with the reaction-diffusion equation, Hyper-FNO shows improved performance and can adapt to the change in the parameters.

TABLE 5
2d Darcy Flow with Translation [−5, −3, 0, 3, 5] × [−3, 0, 3].

| Model | train MSE | test MSE | train l₂ | test l₂ |
|---|---|---|---|---|
| U-Net2d | 6.05e−05 ± | 7.95e−05 ± | 9.20e−02 ± | 1.05e−01 ± |
| | 1.03e−06 | 8.32e−06 | 8.26e−04 | 4.66e−03 |
| FNO | 5.62e−05 ± | 6.01e−05 ± | 9.19e−02 ± | 9.17e−02 ± |
| | 1.57e−07 | 3.62e−07 | 1.82e−04 | 6.50e−04 |
| Hyper-FNO | 5.96e−05 ± | 5.04e−05 ± | 9.74e−02 ± | 8.46e−02 ± |
| | 1.30e−06 | 9.35e−07 | 1.08e−03 | 1.06e−03 |

In some experiments, the steady-state solution of 2-d Darcy Flow over the unit square, whose viscosity term a(x) is an input of the system, is considered. The solution of the steady-state is defined by the following equation

−∇(a(x−λ)∇u(x))=ƒ(x),x∈(0,1)² (41)

u(x)=0,x∈∂(0,1)² (42)

where the viscosity term is shifted by the parameters λ=[λₓ, λ_{y}]^{T}.

Table 5 shows the performance of Hyper-FNO to model the change in the parameters for the steady-state solution. The performance gain is somehow limited in this case. The effect of the change in the parameter of the Darcy Flow is to shift the viscosity term in the 2d coordinates. The limited improvement is related to the limited capacity of FNO to capture this type of parameter change, which is indicated by the smaller difference in the test error between U-Net2d and FNO than in the other PDE cases.

In addition to the foregoing Tables, FIGS. 12a-12d illustrate a comparison of FNO and hyper-FNO in testing and training. FIG. 12a illustrates FNO data in testing and FIG. 12b illustrates FNO data in training. FIG. 12c illustrates hyper-FNO data in testing and FIG. 12d illustrates hyper-FNO data in training.

Hyper-FNO is a method that improves the adaptability of an FNO to various parameters of a physical system that is being modeled. Furthermore, the disclosed hyper-FNO is agnostic of the actual system and can be adapted in a variety of fields and uses for positive societal impact.

Through a hyper-FNO, a method is provided to adapt the FNO architecture over a wide range of parameters of the PDE. Significant improvement is gained over different physics systems, such as the Burgers equation, the reaction-diffusion, and the Darcy flow. Meta-learning for Physics Informed Machine Learning is an important direction of research and a method in this direction that allows us to model to adapt to new environments is disclosed. In some embodiments, In the future, the parameters of the PDE may be automatically learned using Bayesian Optimization.

A Navier-Stokes equation is considered, the equation being defined by

$${\partial }_{t} ρ + ∇ \cdot v = 0 , \qquad ( 43 )$$

$$ρ ( {\partial }_{t} v + v \cdot ∇ v ) = - ∇ p + η Δ v + ( ζ + \frac{η}{3} ) ∇ ( ∇ \cdot v ) , \qquad \text{(44)}$$

$${c}_{s}^{2} = ( \partial p / \partial ρ ) s , \qquad ( 45 )$$

where cₛ is the sound velocity, and η and ζ are shear and bulk viscosity, respectively. The above equations have more parameters than the incompressible Navier-Stokes equations, that is, the bulk viscosity ζ and mach number v_{c}/cₛ where v_{c} is the characteristic velocity in the system. In this case, the next step value can be recursively predicted after observing the first t₀=10 samples, allowing predictions for t₀<t≤T.

TABLE 6
Experiments in computational fluid dynamics (CFD).

| Model | train MSE | test MSE | train l₂ | test l₂ |
|---|---|---|---|---|
| U-Net2d | 3.20e+02 | 1.45e+02 | 8.08e+00 | 7.62e+00 |
| FNO | 9.99e−02 | 3.71e−01 | 2.43e−01 | 4.70e−01 |
| Hyper-FNO | 4.77e−02 | 3.22e−01 | 1.94e−01 | 4.45e−01 |

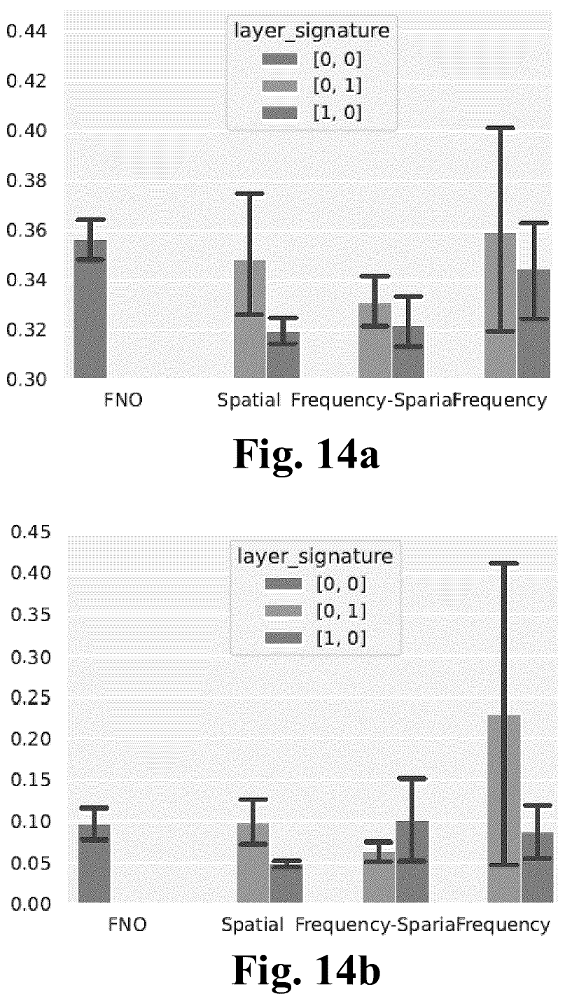

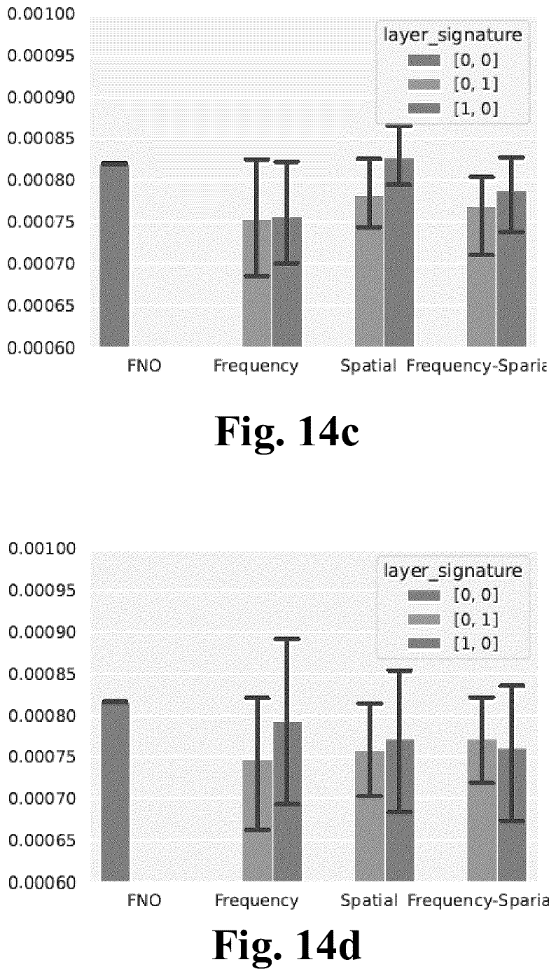

In FIGS. 14a and 14b, the mean squared error (MSE) is plotted in a CFD equation. In FIGS. 14c and 14d, the MSE is plotted in a reaction-diffusion equation. In FIGS. 14a and 14c, testing datasets were used. In FIGS. 14b and 14d, training datasets were used. As shown in FIGS. 14a and 14b, the most effective architecture is to allow parameters to be generated by the hyper-FNO on only the first layer in the spatial domain, while for the reaction-Diffusion equation of FIGS. 14c and 14d, the most effective architecture is to generate the last layer in the frequency domain. A higher variation in the training phase is also observed, rather than in the testing phase, showing that for some parameters the hyper-FNO has difficulty adapting to a change in parameters, but showing an overall performance improvement. The effect on the PDE parameter and on the solution is reflected in the architecture. For example, if the change in parameter has a large impact on the Green's spatial convolution function, the discretization of this kernel may lead to higher error, while if the change in PDE has a large effect in the frequency domain, then this is beneficial to model the change in the spatial domain.

In an exemplary implementation, a rate of change of a solution as a function of change in a PDE parameter can be determined. Specifically, a difference between the original solution and the solution after an infinitesimal change Δλ is computed. The computed difference is

∫_{T,Ω}∥U′(t,ω)−U(t,ω)∥dtdω=∫_{T,Ω}∥−4ω²tG(t,ω)ΔλU(0,ω)∥dtdω=|Δλ|∫_{T,Ω}∥4ω²tG(t,ω)U(0,ω)∥dtdω (46)

with U′(t, ω)=(∂_{λ}G(t, ω)Δλ)U(0, ω). For Δλ≠0, the difference increases with the square of the frequency. This implies that if the parameter of the equation is changed, a change in frequency is induced that is proportional to |Δλ|∫_{T,Ω}∥4ω²tG(t, ω)U(0, ω)∥dtdω. The original operator thus is not more able to accurately predict the function at a later time, accumulating the error in time or frequency.

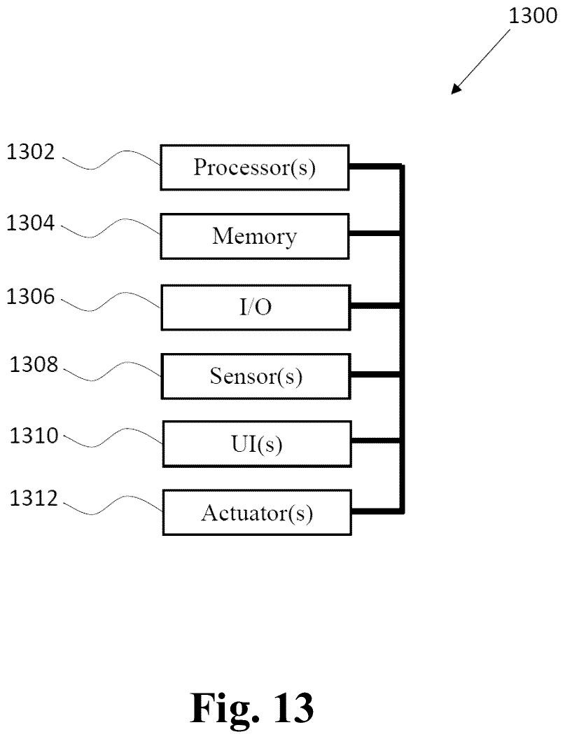

FIG. 13 illustrates a block diagram of an exemplary processing system according to an aspect of the present disclosure. A processing system 1300 can include one or more processors 1302, memory 1304, one or more input/output devices 1306, one or more sensors 1308, one or more user interfaces 1310, and one or more actuators 1312. The processing system 1300 may be an HPC with sufficiently powerful processors 1302 and large enough memory 1304 to perform demanding computational tasks, such as some hyper network training tasks and/or main network training tasks. In some aspects, the processing system 1300 may be less powerful, and therefore more cost and resource efficient, and nevertheless may be sufficient for purposes of testing a main network that has been configured by a hyper network. The processor 1302 is thus configured to execute network training and/or testing as previously described, and/or to implement the foregoing machine learning models as a whole. In some aspects, input output devices 1306 allow for communication of datasets, observational data, or live data to the processor 1302 such that an executed machine learning model may receive data and output predicted results to an external device. In some aspects, the processor 1302 may be configured to actuate one or more actuators 1312 based on a prediction made by an executed machine learning model.

Processors 1302 can include one or more distinct processors, each having one or more cores. Each of the distinct processors can have the same or different structure. Processors 1302 can include one or more central processing units (CPUs), one or more graphics processing units (GPUs), circuitry (e.g., application specific integrated circuits (ASICs)), digital signal processors (DSPs), and the like. Processors 402 can be mounted to a common substrate or to multiple different substrates.

Processors 1302 are configured to perform a certain function, method, or operation (e.g., are configured to provide for performance of a function, method, or operation) at least when one of the one or more of the distinct processors is capable of performing operations embodying the function, method, or operation. Processors 1302 can perform operations embodying the function, method, or operation by, for example, executing code (e.g., interpreting scripts) stored on memory 1304 and/or trafficking data through one or more ASICs. Processors 1302, and thus processing system 1300, can be configured to perform, automatically, any and all functions, methods, and operations disclosed herein. Therefore, processing system 1300 can be configured to implement any of (e.g., all of) the protocols, devices, mechanisms, systems, and methods described herein.

For example, when the present disclosure states that a method or device performs task “X” (or that task “X” is performed), such a statement should be understood to disclose that processing system 1300 can be configured to perform task “X”. Processing system 1300 is configured to perform a function, method, or operation at least when processors 1302 are configured to do the same.

Memory 1304 can include volatile memory, non-volatile memory, and any other medium capable of storing data. Each of the volatile memory, non-volatile memory, and any other type of memory can include multiple different memory devices, located at multiple distinct locations and each having a different structure. Memory 1304 can include remotely hosted (e.g., cloud) storage.

Examples of memory 1304 include a non-transitory computer-readable media such as RAM, ROM, flash memory, EEPROM, any kind of optical storage disk such as a DVD, a Blu-Ray® disc, magnetic storage, holographic storage, a HDD, a SSD, any medium that can be used to store program code in the form of instructions or data structures, and the like. Any and all of the methods, functions, and operations described herein can be fully embodied in the form of tangible and/or non-transitory machine-readable code (e.g., interpretable scripts) saved in memory 1304.

Input-output devices 406 can include any component for trafficking data such as ports, antennas (i.e., transceivers), printed conductive paths, and the like. Input-output devices 1306 can enable wired communication via USB®, DisplayPort®, HDMI®, Ethernet, and the like. Input-output devices 1306 can enable electronic, optical, magnetic, and holographic, communication with suitable memory 1304. Input-output devices 1306 can enable wireless communication via WiFi®, Bluetooth®, cellular (e.g., LTE®, CDMA®, GSM®, WiMax®, NFC®), GPS, and the like. Input-output devices 1306 can include wired and/or wireless communication pathways.

Sensors 1308 can capture physical measurements of environment and report the same to processors 1302. User interface 1310 can include displays, physical buttons, speakers, microphones, keyboards, and the like. Actuators 1312 can enable processors 1302 to control mechanical forces.

Processing system 1300 can be distributed. For example, some components of processing system 1300 can reside in a remote hosted network service (e.g., a cloud computing environment) while other components of processing system 1300 can reside in a local computing system. Processing system 1300 can have a modular design where certain modules include a plurality of the features/functions shown in FIG. 13. For example, I/O modules can include volatile memory and one or more processors. As another example, individual processor modules can include read-only-memory and/or local caches.

The attached paper “Appendix” forms a part of this disclosure and is hereby incorporated by reference herein in its entirety, including each of the references cited therein.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCES

The following references provide additional background information which may be helpful in understanding aspects of the present disclosure. The entire contents of each of the following references are incorporated by reference herein.
Bessonov, et al., “Methods of Blood Flow Modelling.” MATH. MODEL. NAT. PHENOM. 11, 1-25 (2016).
Jamshidi, et al., “Solving inverse problems of unknown contaminant source in groundwater-river integrated systems using a surrogate transport model based optimization.” WATER 12, no. 9: 2415 (2020).
Chen, et al., “Learning and meta-learning of stochastic advection-diffusion-reaction systems from sparse measurements.” EUROPEAN JOURNAL OF APPLIED MATHEMATICS 32, no. 3: 397-420 (2021).
Belbute-Peres, et al., “HyperPINN: Learning parameterized differential equations with physics-informed hyper networks.” arXiv preprint arXiv:2111.01008 (2021).
Arthurs and King, “Active training of physics-informed neural networks to aggregate and interpolate parametric solutions to the navier-stokes equations.” JOURNAL OF COMPUTATIONAL PHYSICS, 438:110364 (August 2021). ISSN 00219991. doi: 10.1016/j.jcp.2021110364. arXiv: 2005.05092.
Avrutskiy, “Neural networks catching up with finite differences in solving partial differential equations in higher dimensions.” NEURAL COMPUTING AND APPLICATIONS, 32(17): 13425-13440 (September 2020). ISSN 0941-0643, 1433-3058. doi: 10.1007/s00521-020-04743-8. arXiv: 1712.05067.
Chen, et al., “Neural ordinary differential equations.” ADVANCES IN NEURAL INFORMATION PROCESSING SYSTEMS, 31 (2018).
Chen, et al., “Learning and meta-learning of stochastic advection-diffusion-reaction systems from sparse measurements.” arXiv1910.09098 (2019).
Eivazi, et al., “Physics-informed neural networks for solving reynolds-averaged navier-stokes equations.” arXiv:2107.10711 [physics] (July 2021).
Guibas, et al., “Adaptive fourier neural operators: Efficient token mixers for transformers.” arXiv:2111.13587 [cs] (November 2021).
Ha, et al., “Hyper networks.” arXiv:1609.09106 [cs] (December 2016).
Karniadakis, et al., “Physics informed machine learning.” NATURE REVIEWS PHYSICS, 3 (6):422-440 (June 2021). ISSN 2522-5820. doi: 10.1038/s42254-021-00314-5.
Krishnapriyan, et al., “Characterizing possible failure modes in physics-informed neural networks.” ADVANCES IN NEURAL INFORMATION PROCESSING SYSTEMS, 34 (2021).
Li, et al., “Neural operator: Graph kernel network for partial differential equations.” arXiv:2003.03485 [cs, math, stat] (March 2020).
Li, et al., “Fourier neural operator for parametric partial differential equations.” arXiv:2010.08895 [cs, math] (May 2021).
Meng and Karniadakis, “A composite neural network that learns from multi-fidelity data: Application to function approximation and inverse pde problems.” JOURNAL OF COMPUTATIONAL PHYSICS, 401:109020 (January 2020). ISSN 00219991. doi: 10.1016/j.jcp.2019.109020. arXiv:1903.00104.
Mischaikow and Mrozek, “Chaos in the lorenz equations: a computer-assisted proof” BULLETIN OF THE AMERICAN MATHEMATICAL SOCIETY, 32(1):66-72 (1995).
O'Leary, et al., “Stochastic physics-informed neural networks (spinn): A moment matching framework for learning hidden physics within stochastic differential equations.” arXiv:2109.01621 (September 2021).
Pathak, et al., “Fourcastnet: A global data-driven high-resolution weather model using adaptive fourier neural operators.” arXiv:2202.11214 [physics] (February 2022).
Raissi, et al., “Physics-informed neural networks: A deep learning framework for solving forward and inverse problems involving nonlinear partial differential equations.” JOURNAL OF COMPUTATIONAL PHYSICS, 378:686-707 (February 2019). ISSN 0021-9991. doi:10.1016/j.jcp.2018.10.045.
Raissi, “Deep hidden physics models: Deep learning of nonlinear partial differential equations.” arXiv:1801.06637 [cs, math, stat] (January 2018).
Raissi, et al., “Multistep neural networks for data-driven discovery of nonlinear dynamical systems.” arXiv:1801.01236 [nlin, physics, stat] (January 2018).
Raissi, et al., “Hidden fluid mechanics: A navier-stokes informed deep learning framework for assimilating flow visualization data.” arXiv:1808.04327 [physics, stat](August 2018).
Ronneberger, et al., “Unet: Convolutional networks for biomedical image segmentation.” INTERNATIONAL CONFERENCE ON MEDICAL IMAGE COMPUTING AND COMPUTER-ASSISTED INTERVENTION, 234-241 (2015).
Thuerey, et al., “Physics-based Deep Learning.” (2021). Available at physicsbaseddeeplearning.org.
Tipireddy, et al., “A comparative study of physics informed neural network models for learning unknown dynamics and constitutive relations.” arXiv:1904.04058 [physics] (April 2019).
Domke, “Generic methods for optimization-based modeling.” ARTIFICIAL INTELLIGENCE AND STATISTICS, 318-326 (2012).

What is claimed is:

1. A method for operating a hyper network machine learning system, the method comprising:
training a hyper network configured to generate main network parameters for a main network; and
generating, using the trained hyper network, the main network with the main network parameters, the main network having a machine learning architecture that models a spatial domain and a frequency domain to simulate a physical system.

2. The method of claim 1,
wherein the main network has a Fourier neural operator architecture comprising a plurality of Fourier layers each having a frequency and spatial component, and
wherein the hyper network generating the main network parameters comprises generating parameters for the Fourier layers.

3. The method of claim 2,
wherein during training of the hyper network, the hyper network modifies the Fourier layers based on a Taylor expansion around a learned configuration to determine updated parameters for the Fourier layers, and
wherein the updated parameters are changed in both the frequency and spatial component.

4. The method of claim 1, the method further comprising obtaining a dataset based on experimental or simulation data generated with different parameter configurations, the dataset comprising a plurality of inputs and a plurality of outputs corresponding to the inputs, wherein the hyper network is trained using the dataset.

5. The method of claim 4, wherein the training comprises:
simulating, via the main network generated with the main network parameters, the physical system to determine a simulation result based on the at least one input of the dataset;
comparing the simulation result against at least one output corresponding to the at least one input from the dataset; and
updating the main network parameters based on the comparison result.

6. The method of claim 5, wherein the training of the hyper network is iteratively conducted until the simulation result is within a predetermined tolerance threshold when compared to the at least one output.

7. The method of claim 1, the method further comprises receiving system parameters by the hyper network, the system parameters corresponding to the physical system targeted for simulation,
wherein generating the main network with the main network parameters comprises the hyper network generating the main network parameters based on the hyper network parameters and the system parameters.

8. The method of claim 1,
wherein the hyper network comprises Fourier layers each having a frequency and spatial component with corresponding hyper network parameters, and
wherein the method further comprises receiving system parameters by the hyper network, the system parameters being configured to adapt the Fourier layers to the physical system targeted for simulation.

9. The method of claim 1,
wherein the hyper network comprises Fourier layers each having a frequency and spatial component with corresponding hyper network parameters, and
wherein the method further comprises adapt the Fourier layers to the physical system targeted for simulation based on system parameters,
wherein the system parameters are determined by learning a representation of the system parameters according to a bilevel problem.

10. The method of claim 1, wherein the hyper network comprises hyper network parameters corresponding to the spatial domain and the frequency domain,
wherein training the hyper network comprises updating the hyper network parameters using stochastic gradient descent based on a training database comprises input and output pairs until a target loss threshold is reached, and
wherein the generating of the main network is performed after completing the training of the hyper network and comprises receiving system parameters associated with the target physical system; and generating the main network parameters based on the hyper network parameters and the system parameters.

11. The method of claim 1, comprising instantiating the main network on a computer system and operating the man network to simulate the target physical system.

12. The method of claim 11, comprising:
receiving input data, simulating the physical system based on the input data to provide a simulation result; and
determining whether to activate an alarm or hardware control sequence based on the simulation result.

13. The method of claim 1, comprising parameterizing a meta-learning network by modifying only system parameters, wherein the main network based on the main network parameters generated by the hyper network includes fewer parameters than the hyper network.

14. A tangible, non-transitory computer-readable medium having instructions thereon which, upon being executed by one or more hardware processors, alone or in combination, provide for execution of the method of claim 1.

15. A system comprising one or more hardware processors which, alone or in combination, are configured to provide for execution of the following steps:
training a hyper network configured to generate main network parameters for a main network; and
generating, using the trained hyper network, the main network with the main network parameters, the main network having a machine learning architecture that models a spatial domain and a frequency domain to simulate a physical system.
